(19) United States
(12) Patent Application Publication
(10) Pub. No.: US 2026/0365880 A1
(43) Pub. Date: Nov. 19, 2026

(54) KIT AND METHOD FOR PRODUCING A SEMICONDUCTOR DEVICE

(71) Applicants: FUJIFILM Corporation, Tokyo (JP); FUJIFILM Electronic Materials U.S.A., Inc., North Kingstown, RI (US)

(72) Inventors: Tetsuya KAMIMURA, Shizuoka (JP); Atsushi MIZUTANI, Shizuoka (JP); Bin HU, Mesa, AZ (US); Yannan LIANG, Mesa, AZ (US); Nobuaki SUGIMURA, Mesa, AZ (US); Ting-Kai HUANG, Mesa, AZ (US); Hanyu FAN, Mesa, AZ (US); Wei LI, Mesa, AZ (US); Hyosang LEE, Mesa, AZ (US)

(73) Assignees: FUJIFILM Corporation, Tokyo (JP); FUJIFILM Electronic Materials U.S.A., Inc., North Kingstown, RI (US)

(21) Appl. No.: 19/710,368

(22) Filed: Jun. 16, 2026

Related U.S. Application Data
(63) Continuation of application No. PCT/JP2024/043720, filed on Dec. 11, 2024.
(60) Provisional application No. 63/613,763, filed on Dec. 22, 2023.

(51) Int. Cl. C09G 1/02; C09K 13/00; H10P 52/40; H10P 70/00

(52) U.S. Cl. CPC C09G 1/02; C09K 13/00; H10P 52/403; H10P 52/407; H10P 70/237; H10P 70/277

(57) ABSTRACT

An object is to provide a kit that includes a polishing fluid and a washing liquid which may enhance the flatness of a processed object and reduce the likelihood of organic residues remaining on the processed object when a processing object is subjected to chemical mechanical polishing using the kit and subsequently cleaned using the kit and a method for producing a semiconductor device in which the above kit is used.

A kit used for chemical mechanical polishing of a processing object and cleaning of the processing object that has been subjected to the chemical mechanical polishing includes a polishing fluid and a washing liquid, the polishing fluid including abrasive grains and a nonionic surfactant, the polishing fluid having a pH of 7.0 or more, the washing liquid including at least one first compound selected from the group consisting of xanthine, a xanthine derivative, adenine, and an adenine derivative and at least one second compound other than the first compound, the second compound being selected from the group consisting of a secondary amine compound, a tertiary amine compound, and a quaternary ammonium compound.

### CROSS-REFERENCE TO RELATED APPLICATIONS

This application is a Continuation of PCT International Application No. PCT/JP2024/043720 filed on Dec. 11, 2024, which claims priority under 35 U.S.C. § 119(e) to U.S. Patent Application No. 63/613,763 filed on Dec. 22, 2023. The above applications are hereby expressly incorporated by reference, in their entirety, into the present application.

### BACKGROUND OF THE INVENTION

### 1. Field of the Invention

The present invention relates to a kit and a method for producing a semiconductor device.

### 2. Description of the Related Art

In the development of semiconductor devices, such as a semiconductor large-scale integrated circuit (LSI), there have been demands for increasing the density of the semiconductor devices and the degree of integration of the semiconductor devices by reducing the size of wires and laminating the wires on top of one another in order to reduce the size of the semiconductor devices and increase the speed of the semiconductor devices. In response to the above demands, in the production of semiconductor devices, chemical mechanical polishing (CMP) process has been used planarization of bare wafers, planarization of interlayer dielectrics, formation of metal plugs, formation of buried wires, and the like.

In a CMP process, residues, such as the abrasive grains used in the CMP process and metal constituents derived from polished wire metal films and/or barrier metals, may remain on the surface of a semiconductor substrate after polishing. Accordingly, a step of removing these residues using a washing liquid is commonly conducted subsequent to a CMP process.

In the production of semiconductor devices described above, there have been a variety of demands for the properties and compositions of the members used in each of the above steps, depending on the constituents and uses of an object that is to be processed (hereinafter, referred to as “processing object”). For example, US2016/075971A discloses a washing liquid that includes a corrosion inhibitor and a surfactant, which is a cleaning composition that enables efficient removal of residues and contaminants produced subsequent to CMP from the surface of an electronic device without degrading low-k materials or copper wire materials, and a cleaning method.

### SUMMARY OF THE INVENTION

When a processing object is subjected to chemical mechanical polishing and the processing object that has been subjected to chemical mechanical polishing is cleaned, it is required that the processed object have excellent flatness and the amount of organic residues that remain on the processed object be small. The inventor of the present invention subjected a processing object to chemical mechanical polishing and cleaned the processing object that had been subjected to chemical mechanical polishing using the polishing fluid and the washing liquid described in US2016/075971A.

Consequently, the inventor found that the planarization of the processing object and the removal of the organic residues cannot be achieved simultaneously at sufficient levels.

Accordingly, an object of the present invention is to provide a kit that includes a polishing fluid and a washing liquid which may enhance the flatness of the processed object and reduce the likelihood of organic residues remaining on the processed object when the processing object is subjected to chemical mechanical polishing using the kit and subsequently cleaned using the kit. Another object is to provide a method for producing a semiconductor device in which the above kit is used.

### Solution of Problem

The inventors of the present invention conducted extensive studies in order to achieve the above objects and consequently found that the objects may be achieved by the following structures.
[1] A kit used for chemical mechanical polishing of a processing object and cleaning of the processing object that has been subjected to the chemical mechanical polishing, the kit including:
a polishing fluid; and
a washing liquid,
the polishing fluid including abrasive grains and a nonionic surfactant, the polishing fluid having a pH of 7.0 or more,
the washing liquid including at least one first compound selected from the group consisting of xanthine, a xanthine derivative, adenine, and an adenine derivative and at least one second compound other than the first compound, the second compound being selected from the group consisting of a secondary amine compound, a tertiary amine compound, and a quaternary ammonium compound.
[2] The kit according to [1], wherein the washing liquid has a pH of 10.0 to 14.0.
[3] The kit according to [1] or [2], wherein the washing liquid includes two or more second compounds.
[4] The kit according to [3], wherein at least one of the two or more second compounds is a tertiary amine compound.
[5] The kit according to any one of [1] to [4], wherein the washing liquid includes three or more second compounds.
[6] The kit according to [5], wherein at least one of the three or more second compounds is a tertiary amine.
[7] The kit according to any one of [1] to [6], wherein at least one of the second compound is a compound selected from the group consisting of the compound represented by Formula (A1) described below and the compound represented by Formula (A2) described below.
[8] The kit according to [7], wherein the washing liquid includes two or more second compounds, and at least two of the two or more second compounds are compounds selected from the group consisting of the compound represented by Formula (A1) and the compound represented by Formula (A2).
[9] The kit according to any one of [1] to [8], wherein a content of the first compound is 0.10% to 10.0% by mass of a total solid content in the washing liquid.
[10] The kit according to any one of [1] to [9], wherein a content of the second compound is 75.08 by mass or more of a total solid content in the washing liquid.
[11] The kit according to any one of [1] to [10], wherein a mass ratio of a content of the second compound to a content of the first compound is 10.00 to 1000.00.
[12] The kit according to any one of [1] to [11], wherein the pH of the polishing fluid is 8.5 to 11.0.
[13] The kit according to any one of [1] to [12], wherein at least one of the polishing fluid or the washing liquid further includes an organic acid.
[14] The kit according to [13], wherein the organic acid includes at least one organic acid selected from the group consisting of a polyvalent carboxylic acid and a polyvalent phosphonic acid.
[15] The kit according to any one of [1] to [14], wherein the polishing fluid further includes an alcohol.
[16] The kit according to [15], wherein a content of the alcohol is 0.1 to 1000 ppm by mass of a total mass of the polishing fluid.
[17] The kit according to or [16], wherein the alcohol is an alcohol selected from the group consisting of methanol, ethanol, 1-propanol, and isopropanol.
[18] The kit according to any one of [1] to [17], wherein the nonionic surfactant is an alcohol alkoxylate.
[19] The kit according to any one of [1] to [18], wherein a ratio of a content of the nonionic surfactant relative to a total mass of the polishing fluid to a content of the second compound relative to a total mass of the washing liquid is 0.0035 to 3.5.
[20] The kit according to any one of [1] to [19], wherein the processing object includes copper.
[21] A method for producing a semiconductor device in which the kit according to any one of [1] to is used, the method including:
a step 1 of subjecting a processing object to chemical mechanical polishing using the polishing fluid, and
a step 2 of, subsequent to the step 1, cleaning the processing object that has been subjected to the chemical mechanical polishing using the washing liquid.
[22]. The method according to claim [21], further comprising: a step 1a, after step 1 and prior to step 2, of pad washing the processing object subjected to chemical mechanical polishing using the washing liquid as a composition for pad washing.

According to the present invention, a kit that includes a polishing fluid and a washing liquid which may enhance the flatness of the processed object and reduce the likelihood of organic residues remaining on the processed object when the processing object is subjected to chemical mechanical polishing using the kit and subsequently cleaned using the kit may be provided.

Furthermore, a method for producing a semiconductor device in which the above kit is used may be provided.

### DESCRIPTION OF THE PREFERRED EMBODIMENTS

Details of the present invention are described below.

The elements of the present invention may be described on the basis of typical embodiments of the present invention below. However, the present invention is not limited to the embodiments.

The meanings of the terms and expressions used in the specification are described below.

In the specification, a numerical range expressed using “to” means the range specified by the lower and upper limits described before and after “to”, respectively.

In the specification, in the case where a composition includes a plurality of substances that correspond to a component of the composition, the “content” of the component in the composition is the total content of the substances in the composition unless otherwise specified.

In the specification, the expression “the total solid content in a polishing fluid” refers to the total mass of all the constituents included in the polishing fluid which are other than a solvent, such as water or an organic solvent, and the expression “the total solid content in a washing liquid” refers to the total mass of all the constituents included in the washing liquid which are other than a solvent, such as water or an organic solvent.

The compounds described in the specification may include a structural isomer, an optical isomer, or an isotope unless otherwise specified. The types of the structural isomers, optical isomers, or isotopes may be only one or two or more.

In the specification, in the case where a plurality of substituents, linking groups, or the like (hereinafter, referred to as “substituents or the like”) are denoted with a specific symbol, or a plurality of substituents or the like are defined collectively, the substituents or the like may be the same as or different from one another. The same applies to the definition of the number of the substituents or the like.

The directions in which the divalent groups described in the specification are bonded to others are not limited unless otherwise specified. For example, in the case where Y included in a compound represented by “X—Y—Z” is —COO—, Y may be either —CO—O— or —O—CO— and the compound may be either “X—CO—O—Z” or “X—O—CO—Z”.

In the specification, the terms “ppm”, “ppb”, and “ppt” refer to “parts-per-million (10⁻⁶)”, “parts-per-billion (10⁻⁹)”, and “parts-per-trillion (10⁻¹²)”, respectively.

In the specification, the terms “weight-average molecular weight (Mw)” and “poly dispersity index (PDI)” refer to values measured by gel permeation chromatography (GPC) in terms of polyethylene glycol unless otherwise specified.

### {Kit}

Details of the kit according to the present invention are described below.

The kit according to the present invention is a kit used for chemical mechanical polishing of a processing object and cleaning of the processing object that has been subjected to the chemical mechanical polishing, the kit including:
a polishing fluid; and
a washing liquid,
the polishing fluid including abrasive grains and a nonionic surfactant, the polishing fluid having a pH of 7.0 or more,
the washing liquid including at least one first compound selected from the group consisting of xanthine, a xanthine derivative, adenine, and an adenine derivative and at least one second compound other than the first compound, the second compound being selected from the group consisting of a secondary amine compound, a tertiary amine compound, and a quaternary ammonium compound.

The mechanisms by which the kit according to the present invention, which has the above-described structure, achieves the objects of the present invention are not exactly known. The inventors of the present invention consider the mechanisms as follows.

Note that the following considerations do not limit the mechanisms by which the advantageous effects are produced. In other words, even in the case where the advantageous effects can be produced by mechanisms other than those described below, it is considered that the technique is within the scope of the present invention.

The polishing fluid included in the kit according to the present invention is a polishing fluid that includes abrasive grains and a nonionic surfactant and has a pH of 7.0 or more. It is considered that, since the polishing fluid has the above structure, for example, dishing of the processing object is reduced, the flatness of the processing object, is enhanced, and the likelihood of organic residues remaining on the processing object is reduced consequently.

The washing liquid included in the kit according to the present invention is a washing liquid including at least one first compound selected from the group consisting of xanthine, a xanthine derivative, adenine, and an adenine derivative and at least one second compound other than the first compound, the second compound being selected from the group consisting of a secondary amine compound, a tertiary amine compound, and a quaternary ammonium compound.

It is considered that, when the washing liquid has the above structure, in particular, the organic substances included in the polishing fluid the above-described structure are efficiently removed and, consequently, the likelihood of organic residues remaining on the processing object is reduced.

Note that the expression “enhance the advantageous effects of the present invention” means that, when the kit according to the present invention is applied to the process in which a processing object is subjected to chemical mechanical polishing and the processing object that has been subjected to chemical mechanical polishing is cleaned, at least one of the effect to enhance the flatness of the processed object or the effect to reduce the likelihood of organic residues remaining on the processed object can be produced.

Details of the polishing fluid and the washing liquid that constitute the kit according to the present invention are described below.

### <<Polishing Fluid>>

The kit according to the present invention includes a polishing fluid and a washing liquid.

The polishing fluid includes abrasive grains and a nonionic surfactant and has a pH of 7.0 or more.

Details of each of the constituents of the polishing fluid are described below.

### <Abrasive Grains>

The polishing fluid includes abrasive grains.

The abrasive grains are not limited and may be any abrasive grains used for chemical mechanical polishing in a semiconductor production process. Publicly known abrasive grains may be used. Examples of the abrasive grains include inorganic abrasive grains made of silica, alumina, zirconia, ceria, titania, germania, and silicon carbide; and organic abrasive grains made of polystyrene, polyacryl, and polyvinyl chloride. Among these, silica particles are preferably used as abrasive grains, because they have excellent dispersion stability in the polishing fluid and reduce the formation of scratches (polish flaws) due to CMP.

Examples of the silica particles include, but are not limited to, particles of precipitated silica, fumed silica, and colloidal silica. Among these, colloidal silica particles are preferable. Note that colloidal silica particles are particles of silica (silicon oxide) which are dispersed in a disperse medium in a colloidal form.

The average primary particle size (particle size) of the abrasive grains is preferably 300 nm or less, is more preferably 100 nm or less, and is further preferably 80 nm or less in order to further reduce scratching. The lower limit is preferably 1 nm or more, is more preferably 3 nm or more, and is further preferably 5 nm or more in order to further enhance the dispersion stability of the abrasive grains.

Note that the average primary particle size of the colloidal silica particles is the particle size (median diameter) at which a cumulative distribution value of a volume-basis cumulative particle size distribution curve of the colloidal silica particles is 50%. The cumulative particle size distribution curve is determined by measuring the equivalent circle diameters of the colloidal silica particles with a transmission electron microscope or the like and converting the data into a volume basis. Note that the term “equivalent circle diameter” refers to the diameter of a perfect circle assumed to have the same projected area as the colloidal silica particle observed.

The average aspect ratio of the abrasive grains is preferably 1.5 to 2.0, is more preferably 1.55 to 1.95, and is further preferably 1.6 to 1.9 in order to enhance the polishing power. The average aspect ratio of the abrasive grains is determined by measuring the major- and minor-axis lengths of each of the 100 particles randomly observed with the above transmission electron microscope, calculating aspect the ratio (major-axis length/minor-axis length) of each particle, and calculating the arithmetic average of the 100 aspect ratios. Note that the major-axis length of a particle is the length of the particle in the major axis direction, while the minor-axis length of a particle is the length of the particle in a direction orthogonal to the major axis direction.

The degree of association of the abrasive grains is preferably 1 to 3 in order to further increase the polishing rate. In the specification, the degree of association is determined using the following formula:

Degree of association=Average secondary particle size/Average primary particle size

The average secondary particle size of the abrasive grains is the average particle size of secondary particles, which are formed by the association of a part of the abrasive grains, and can be determined as in the calculation of the average primary particle size described above or using a particle size distribution prepared by dynamic light scattering.

The colloidal silica particles may have a surface-modifying group (e.g., a sulfo group, a phosphonic acid group, a carboxylic group, or an amino group) present on the surfaces. The above group may be ionized in the polishing fluid.

The surface-modified colloidal silica particles are silica particles that have a functional group other than a silanol group (hereinafter, this functional group is also referred to as “surface-modifying group”) as a result of modification of a part of the silanol groups present on the surfaces of the silica particles and that are dispersed in a colloidal form.

The surface-modifying group may be covalently bonded directly onto the surfaces of the silica particles or bonded onto the surfaces of the silica particles with a linking group.

The surface-modifying group is preferably an ionic group. Examples of the ionic group include an anionic group and a cationic group.

Examples of the anionic group include groups represented by —SO₃⁻M⁺, —OSO₃⁻M⁺, —PO₃⁻M⁺, and —OPO₃⁻M⁺.

M⁺ represents a cation. Examples of the cation include, but are not limited to, a proton, a quaternary ammonium cation, and a monovalent metal cation.

In the case where M⁺ is a proton, the groups represented by —SO₃⁻M⁺, —OSO₃⁻M⁺, —PO₃⁻M⁺, and —OPO₃⁻M⁺ are a sulfo group, a sulfonic acid ester group, a phosphonic acid group, and a phosphonic acid ester group, respectively.

The anionic group may be ionized in the polishing fluid. That is, the anionic group may be a group represented by —SO₃⁻, —OSO₃⁻, —PO₃⁻, or —OPO₃⁻. Examples of the cationic group include a group represented by —NH₂.

The group represented by —NH₂ may form a group represented by —NH₃⁺ and may further combine with an anion to form a salt. Examples of the anion include, but are not limited to, a hydroxide ion, a halide ion, a nitrate ion, a sulfate ion, and a phosphate ion.

Among these, the surface-modifying group is preferably a group represented by —SO₃⁻M⁺, —OSO₃⁻M⁺, —PO₃⁻M⁺, —OPO₃⁻M⁺, or —NH₂, and is more preferably a group represented by —SO₃⁻M⁺, —OSO₃⁻M⁺, or —NH₂.

The types of the surface-modifying groups included in the silica particles may be only one or two or more.

Examples of the method for preparing surface-modified colloidal silica particles include, but are not limited to, the methods described in JP2005-162533A and JP2010-269985A. For example, a method of reacting a silane coupling agent having a surface-modifying group or a group that can be converted into a surface-modifying group with a silanol group present on the surfaces of silica particles can be used.

The abrasive grains may be a commercial product. Examples of the commercial colloidal silica particles include PL-1, PL-3, PL-7, PL-10H, PL-5D, PL-3D, PL-2D, PL-1D, PL-07D, PL-5C, PL-3C, and PL-1C (the above are all product names, produced by Fuso Chemical Co., Ltd.).

In the case where commercial colloidal silica particles are used, catalog values of the average primary particle size, the average secondary particle size, the degree of association, and the aspect ratio of the colloidal silica particles are preferentially used.

The content of the abrasive grains is preferably 0.01% to 10% by mass, is more preferably 0.1% to 78 by mass, and is further preferably 1% to 5% by mass of the total mass of the polishing fluid.

The content of the abrasive grains is preferably 5% to 80% by mass, is more preferably 20% to 70% by mass, and is further preferably 40% to 60% by mass of the total solid content of the polishing fluid in consideration of polish efficiency and temporal stability.

Only one type of the abrasive grains may be used alone. Alternatively, two or more types of the abrasive grains may be used. In the case where two or more types of the abrasive grains are used, it is preferable that the total content of the abrasive grains fall within the above range.

### <Nonionic Surfactant>

The polishing fluid includes a nonionic surfactant.

Examples of the nonionic surfactant include a polyalkylene oxide alkyl phenyl ether-based surfactant; an alcohol alkoxylate (polyalkylene oxide alkyl ether)-based surfactant; a block polymer-based surfactant composed of polyethylene oxide and polypropylene oxide; a polyoxyalkylene distyrenated phenyl ether-based surfactant; a polyalkylene tribenzyl phenyl ether-based surfactant; an acetylene polyalkylene oxide-based surfactant; a polyoxyethylene sorbitol fatty acid ester-based surfactant; and a polyoxyethylene alkylamine-based surfactant. Among the above nonionic surfactants, alcohol alkoxylate is preferable.

The alcohol alkoxylate is preferably the compound represented by General Formula (b) below.

R-L¹-(L²O)ₙ—H (b)

In General Formula (b), R represents an alkyl group.

L¹ represents a single bond, an oxygen atom, or an alkylene group that may have an oxygen atom.

L² represents an alkylene group having two or three carbon atoms. A plurality of L² groups may be identical to or different from one another.

n represents a number of two or more.

In General Formula (b) above, the number of carbon atoms included in the alkyl group represented by R is preferably 5 to 25, is more preferably 8 to 20, and is further preferably 10 to 18. The above alkyl group may be either linear or branched.

The number of carbon atoms included in the alkylene group that may have an oxygen atom, which is represented by L¹, is preferably 1 to 20, is more preferably 1 to 10, and is further preferably 1 to 5.

n is preferably 3 to 50, is more preferably 4 to 30, and is further preferably 6 to 20.

Examples of the alkylene group that may have an oxygen atom include —O—CH₂—CH₂— and —O—CH₂—CH₂—CH₂—.

The nonionic surfactant may be a commercial product. Examples of the commercial product include Surfynol 61, 82, 440, 465, and 485, MD20, and DYNOL 604 and 607 represented by Air Products & Chemicals; Olfine STG and Olfine E1010 produced by Nissin Chemical Industry Co., Ltd.; EMULGEN 103, 106, 108, 150, 220, 404, 102 KG, AMIET 320, RHEODOL TW-S320V, 430, 430V, and 460 produced by Kao Corporation; and LF-EP-61 and 40 produced by Verdant Specialty Solutions.

The hydrophile-lipophile balance (HLB) value of the nonionic surfactant is preferably 3 to 20, is more preferably 8 to 17, and is further preferably 8 to 15 in order to enhance the advantageous effects of the present invention. The HLB value is the value calculated using Griffin's formula (20×Mw/M, where Mw represents the molecular weight of a hydrophilic portion, and M represents the molecular weight of the nonionic surfactant). Depending on the situation, the catalog value or a value calculated using another method may be used. The closer to 20 the HLB value, the more hydrophilic the nonionic surfactant. The closer to 0 the HLB value, the more lipophilic the nonionic surfactant.

The content of the nonionic surfactant is preferably 0.001% to 5.0% by mass, is more preferably 0.005% to 1.5% by mass, and is further preferably 0.01% to 1.2% by mass of the total mass of the polishing fluid in order to enhance the advantageous effects of the present invention.

Only one type of the nonionic surfactant may be used alone. Alternatively, two or more types of the nonionic surfactants may be used. In the case where two or more types of the nonionic surfactants are used, it is preferable that the total content of the nonionic surfactants fall within the above range.

### <Organic Acid>

The polishing fluid may include an organic acid. The polishing fluid preferably includes an organic acid in order to enhance the advantageous effects of the present invention. The organic acid is not limited and may be any compound that includes at least one carbon atom and an acidic group.

The organic acid may be a compound having a functional group (i.e., a coordinating group) capable of serving as a ligand.

Examples of the acidic group included in the organic acid include a carboxyl group, a phosphonic acid group, and a sulfo group, and a carboxyl group and a phosphonic acid group are preferable. The number of the acidic groups included in the organic acid is not limited and may be one or more. It is preferable that the above number be two or more. Specifically, the organic acid preferably includes at least one organic acid selected from the group consisting of a polyvalent carboxylic acid and a polyvalent phosphonic acid, more preferably includes a polyvalent carboxylic acid, and further preferably includes a divalent or trivalent carboxylic acid.

The organic acid preferably has a low molecular weight. Specifically, the molecular weight of the organic acid is preferably 600 or less, is more preferably 450 or less, and is further preferably 300 or less. The lower limit for the above molecular weight is preferably 50 or more and is more preferably 100 or more.

The number of carbon atoms included in the organic acid is preferably 1 to 15 and is more preferably 2 to 15.

Examples of the organic acid include an organic acid having a carboxyl group, an organic acid having a phosphonic acid group, and an organic acid having a sulfo group.

Examples of the organic acid having a carboxyl group include a polycarboxylic acid, an aminocarboxylic acid, and a hydroxycarboxylic acid.

Examples of the polycarboxylic acid include malonic acid, oxalic acid, succinic acid, glutaric acid, adipic acid, pimelic acid, sebacic acid, maleic acid, and adipic acid. Malonic acid, oxalic acid, and succinic acid are preferable.

Examples of the aminocarboxylic acid include glycine and derivatives thereof, histidine and derivatives thereof, alanine (2-aminopropionic acid or 3-aminopropionic acid), arginine, asparagine, aspartic acid, cystine, cysteine, glutamine, glutamic acid, isoleucine, leucine, lysine, methionine, phenylalanine, serine, ethionine, threonine, tyrosine, valine, tryptophan, 2-amino-3-aminopropanoic acid, and proline. Glycine and derivatives thereof are preferable.

Examples of the aminocarboxylic acid also include the compounds described in Paragraphs to of JP2016-086094A.

Examples of the glycine derivatives include N,N-di(2-hydroxyethyl)glycine.

Examples of the hydroxycarboxylic acid include citric acid, malic acid, glycolic acid, gluconic acid, heptonic acid, tartaric acid, lactic acid, phenyllactic acid, hydroxyphenyllactic acid, and phenylsuccinic acid. Citric acid, tartaric acid, and lactic acid are preferable.

Examples of the organic acid having a phosphonic acid group include a phosphonic acid. Specific examples thereof include etidronic acid (HEDP), 1-hydroxyethylidene-1,1′-diphosphonic acid (HEDPO), 1-hydroxypropylidene-1,1′-diphosphonic acid, 1-hydroxybutylidene-1,1′-diphosphonic acid, ethylamino bis(methylenephosphonic acid), dodecylamino bis(methylenephosphonic acid), nitrilotris(methylenephosphonic acid) (NTPO), ethylenediamine bis(methylenephosphonic acid) (EDDPO), 1,3-propylenediamine bis(methylenephosphonic acid), ethylenediamine tetra(methylenephosphonic acid) (EDTPO), ethylenediamine tetra(ethylenephosphonic acid), 1,3-propylenediamine tetra(methylenephosphonic acid) (PDTMP), 1,2-diaminopropane tetra(methylenephosphonic acid), 1,6-hexamethylenediamine tetra(methylenephosphonic acid), diethylenetriamine penta(methylenephosphonic acid) (DEPPO), diethylenetriamine penta (ethylenephosphonic acid), triethylenetetramine hexa(methylenephosphonic acid), and triethylenetetramine hexa (ethylenephosphonic acid).

Among the above organic acids having a phosphonic acid group, HEDP, HEDPO, and EDTPO are preferable.

Examples of the organic acid having a phosphonic acid group also include the compounds described in Paragraphs [0026] to [0036] of WO2018/020878A and the compounds (i.e., (co)polymers) described in Paragraphs [0031] to [0046] of WO2018/030006A. The contents of the above patent documents are incorporated herein.

The organic acid preferably includes at least one selected from the group consisting of a polycarboxylic acid, an aminocarboxylic acid, and a phosphonic acid and more preferably includes at least two selected from the group consisting of a polycarboxylic acid, an aminocarboxylic acid, and a phosphonic acid.

In particular, the organic acid preferably includes at least one selected from the group consisting of malonic acid, formic acid, oxalic acid, citric acid, tartaric acid, succinic acid, glycine, HEDP, HEDPO, and EDTPO and more preferably includes at least one selected from the group consisting of malonic acid, glycine, and HEDP.

The content of the organic acid is preferably 0.001% to 5.0% by mass, is more preferably 0.01% to 3.0% by mass, and is further preferably 0.01% to 1.0% by mass of the total mass of the polishing fluid.

The content of the organic acid is preferably 0.1% to 20.0% by mass and is more preferably 0.5% to 10.0% by mass of the total solid content of the polishing fluid.

Only one type of the organic acid may be used alone. Alternatively, two or more types of the organic acids may be used. In the case where two or more types of the organic acids are used, it is preferable that the total content of the organic acids fall within the above range.

### <Alcohol>

The polishing fluid may include an alcohol. The polishing fluid preferably includes an alcohol in order to enhance the advantageous effects of the present invention.

The alcohol is a compound other than any of the above-described nonionic surfactant and organic acid.

The alcohol may be a polyhydric alcohol having a plurality of hydroxyl groups and is preferably a monohydric alcohol.

The molecular weight of the alcohol is preferably, but not limited to, 32 to 290, is more preferably 32 to 100, and is further preferably 32 to 80.

In order to enhance the advantageous effects of the present invention, the alcohol is preferably an alkyl alcohol and is more preferably an alcohol selected from the group consisting of methanol, ethanol, 1-propanol, and isopropanol.

The content of the alcohol is preferably 5000 ppm by mass or less, is more preferably 2000 ppm by mass or less, and is further preferably 1000 ppm by mass or less of the total mass of the polishing fluid in order to further enhance resistance to interface corrosion. The lower limit for the alcohol content is commonly 0.01 ppm by mass or more and is preferably 0.1 ppm by mass or more.

Only one type of the alcohol may be used alone. Alternatively, two or more types of the alcohols may be used. In the case where two or more types of the alcohols are used, it is preferable that the total content of the alcohols fall within the above range.

### <Water>

The polishing fluid may include water.

The water included in the polishing fluid is not limited; distilled water, deionized (DI) water, and pure water (ultrapure water) can be used.

The content of the water is not limited and may be the balance of the constituents that may be included in the polishing fluid.

The content of the water is preferably 55.0% to 99.0% by mass, is more preferably 75.0% to 97.0% by mass, and is further preferably 80.0% to 97.0% by mass of the total mass of the polishing fluid.

### <Oxidizing Agent>

The polishing fluid may include an oxidizing agent. The polishing fluid preferably includes an oxidizing agent in consideration of polish efficiency.

The oxidizing agent is preferably, but not limited to, a compound capable of oxidizing copper. Examples of the oxidizing agent include hydrogen peroxide, ozone water, a rare-earth metal oxide, a percarbonic acid salt, a permanganic acid salt, a cerium compound, a ferricyanide, and periodic acid, persulfuric acid, chloric acid, hypochlorous acid, bromic acid, iodic acid, chromic acid, perboric acid, peracetic acid, perbenzoic acid, potassium dichromate, and salts thereof. Hydrogen peroxide is preferable.

The content of the oxidizing agent is preferably 0.1% to 15.0% by mass, is more preferably 0.5% to 10.0% by mass, and is further preferably 1.0% to 5.0% by mass of the total mass of the polishing fluid.

The content of the oxidizing agent is preferably 5.0% to 80.0% by mass, is more preferably 20.0% to 70.0% by mass, and is further preferably 40.0% to 60.0% by mass of the total solid content of the polishing fluid in consideration of polish efficiency and storage stability.

Only one type of the oxidizing agent may be used alone. Alternatively, two or more types of the oxidizing agents may be used. In the case where two or more types of the oxidizing agents are used, it is preferable that the total content of the oxidizing agents fall within the above range.

### <Other Constituent>

The polishing fluid may include a constituent other than any of the above-described constituents.

Examples of the other constituent include a pH-controlling agent, a surfactant other than the nonionic surfactant, a water-soluble polymer, an anticorrosive, and an organic solvent other than the alcohol.

pH-Controlling Agent

The polishing fluid may include a pH-controlling agent for adjusting and maintaining the pH of the polishing fluid.

The pH-controlling agent includes a basic compound and an acidic compound which are other than any of the above-described compounds that may be included in the polishing fluid. Note that the pH of the polishing fluid may be adjusted by changing the amounts of the above constituents added.

The basic compound is a compound that exhibits alkalinity (i.e., pH of more than 7.0) in an aqueous solution.

Examples of the basic compound include basic inorganic compounds. Examples thereof include alkali metal hydroxides, such as sodium hydroxide and potassium hydroxide; alkaline-earth metal hydroxides; and ammonia.

The acidic compound is a compound that exhibits acidity (i.e., pH of less than 7.0) in an aqueous solution.

Examples of the acidic compound include inorganic acids. Examples thereof include hydrochloric acid, sulfuric acid, sulfurous acid, nitric acid, nitrous acid, phosphoric acid, hexafluorophosphoric acid, and boric acid.

The acidic compound may be a salt of an acidic compound which serves as an acid or an acid ion (anion) in an aqueous solution.

The content of the pH-controlling agent may be selected in accordance with the types and amounts of the other constituents and the intended pH of the washing liquid. For example, the content of the pH-controlling agent is preferably 0.01% to 10% by mass and is more preferably 0.1% to 8% by mass of the total mass of the polishing fluid.

The content of the pH-controlling agent is preferably 0.01% to 80% by mass and is more preferably 0.1% to 60% by mass of the total solid content of the polishing fluid.

Only one type of the pH-controlling agent may be used alone. Alternatively, two or more types of the pH-controlling agents may be used. In the case where two or more types of the pH-controlling agents are used, it is preferable that the total content of the pH-controlling agents fall within the above range.

### Surfactant

The polishing fluid may include a surfactant other than the nonionic surfactant. The surfactant other than the nonionic surfactant is not limited and may be any compound that has a hydrophilic group and a hydrophobic group (i.e., a lipophilic group) in one molecule and also has an ionic portion. Examples thereof include a cationic surfactant, a zwitterionic surfactant, and an anionic surfactant.

Examples of the cationic surfactant include an alkylpyridium-based surfactant and an alkylamine acetate-based surfactant.

Examples of the zwitterionic surfactant include a carboxybetaine-type zwitterionic surfactant, a sulfobetaine-type zwitterionic surfactant, an aminocarboxylic acid salt, imidazolinium betaine, lecithin, an alkylamine oxide, and mixtures thereof.

Examples of the anionic surfactant include a phosphoric acid ester-based surfactant having a phosphoric acid ester group serving as a hydrophilic group (i.e., an acidic group) and a sulfuric acid ester-based surfactant having a sulfuric acid ester group serving as a hydrophilic group (i.e., an acidic group).

For example, the compounds described in Paragraphs [0116] to [0123] of WO2022/044893A may be used as a surfactant. The contents of the above patent document are incorporated herein.

### Water-Soluble Polymer

The polishing fluid may include a water-soluble polymer. Examples of the water-soluble polymer include polyvinyl alcohol, polyvinylpyrrolidone, and polyacrolein.

### Anticorrosive

The polishing fluid may include an anticorrosive. The anticorrosive is a compound that reduces the corrosion of metals present on the surface of the processing object.

The anticorrosive is preferably a heteroaromatic ring compound that has three or more nitrogen atoms per molecule and a heterocyclic structure. The three or more nitrogen atoms are preferably the elements that constitute the heteroaromatic ring. Preferable examples of the anticorrosive include an unsubstituted or substituted benzotriazole.

The compounds described in Paragraphs [0046] to [0050] of WO2021/166571A may also be used as an anticorrosive. The contents of the above patent document are incorporated herein. The content of the anticorrosive is preferably 0.0001% to 5.0% by mass, is more preferably 0.005% to 3.0% by mass, and is further preferably 0.008% to 0.8% by mass of the total mass of the polishing fluid.

The content of the anticorrosive is preferably 0.01% to 40.0% by mass, is more preferably 0.015% to 15.0% by mass, and is further preferably 0.1% to 5.0% by mass of the total solid content of the polishing fluid.

Only one type of the anticorrosive may be used alone. Alternatively, two or more types of the anticorrosives may be used. In the case where two or more types of the anticorrosives are used, it is preferable that the total content of the anticorrosives fall within the above range.

### Organic Solvent

The polishing fluid may include an organic solvent other than the alcohol.

Examples of the organic solvent include publicly known organic solvents, such as a glycol diether-based solvent and a ketone-based solvent.

The organic solvent is preferably mixed with water at a predetermined ratio.

For example, the compounds described in Paragraphs [0139] and [0140] of WO2022/044893A may be used as an organic solvent. The contents of the above patent document are incorporated herein.

### (Physical Properties of Polishing Fluid)

The properties of the polishing fluid are described in detail below.

<pH>

The pH of the polishing fluid is 7.0 or more.

In order to further enhance polish efficiency and the advantageous effects of the present invention, the pH of the polishing fluid is preferably 7.0 to 12.0, is more preferably 8.5 to 11.0, and is further preferably 9.0 to 10.5.

The pH of the polishing fluid may be adjusted using the pH-controlling agent described above.

The pH of the polishing fluid can be measured with a publicly known pH meter by a method conforming to JIS Z 8802-1984. The pH measurement is done at 25 °C.

### (Method for Producing Polishing Fluid)

The method for producing the polishing fluid is not limited; publicly known production methods may be used. For example, the polishing fluid may be produced by mixing the above-described constituents with one another at predetermined concentrations. Alternatively, the polishing fluid may be produced by preparing a concentrate and subsequently diluting the concentrate.

When the constituents are mixed with one another, the constituents may be mixed in one batch or in a plurality of batches in small amounts. The constituents to be mixed may be in the form of either a solid or an aqueous solution.

The stirring device and method used for mixing are not limited. Stirring devices and methods publicly known as a stirrer or disperser may be used. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

### <<Washing Liquid>>

Details of the washing liquid are described below.

The washing liquid includes at least one first compound selected from the group consisting of xanthine, a xanthine derivative, adenine, and an adenine derivative and at least one second compound that is other than the first compound and selected from the group consisting of a secondary amine compound, a tertiary amine compound, and a quaternary ammonium compound.

### <First Compound>

The washing liquid includes a first compound. The first compound is at least one compound selected from the group consisting of xanthine, a xanthine derivative, adenine, and an adenine derivative.

The xanthine derivative is a compound formed as a result of a part of xanthine being replaced with another atom or substituent. Examples of the xanthine derivative include the compound represented by Formula (C1).

The adenine derivative is a compound formed as a result of a part of adenine being replaced with another atom or substituent. Examples of the adenine derivative include the compound represented by Formula (C2).

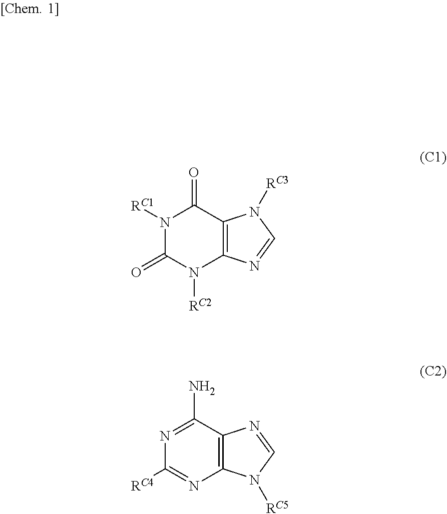

In Formula (C1), R^{C1} to R^{C3} each independently represent a hydrogen atom, an unsubstituted or substituted alkyl group, an unsubstituted or substituted amino group, a thiol group, a hydroxyl group, a halogen atom, an unsubstituted or substituted saccharide group, or an unsubstituted or substituted polyoxyalkylene group-containing group.

The alkyl group may be linear, branched, or cyclic.

The number of carbon atoms included in the alkyl group is preferably 1 to 10, is more preferably 1 to 5, and is further preferably 1 to 3.

Examples of the saccharide group include a group formed as a result of one hydroxyl group being removed from a saccharide selected from the group consisting of a monosaccharide, a disaccharide, and a polysaccharide. A group formed as a result of one hydroxyl group being removed from a monosaccharide is preferable.

Examples of the monosaccharide include pentoses, such as ribose, deoxyribose, arabinose, and xylose, trioses, tetroses, hexoses, and heptoses. Pentoses are preferable. Ribose, deoxyribose, arabinose, and xylose are more preferable. Ribose and deoxyribose are further preferable.

Examples of the disaccharide include sucrose, lactose, maltose, trehalose, turanose, and cellobiose.

Examples of the polysaccharide include glycogen, starch, and cellulose.

The saccharide may be either linear or cyclic and is preferably cyclic.

Examples of the cyclic saccharide include a furanose ring and a pyranose ring.

The unsubstituted or substituted polyoxyalkylene group-containing group is a group a part of which includes an unsubstituted or substituted polyoxyalkylene group.

Examples of the polyoxyalkylene group constituting the polyoxyalkylene group-containing group include a polyoxyethylene group, a polyoxypropylene group, and a polyoxybutylene group. A polyoxyethylene group is preferable.

Examples of the substituent included in the alkyl group, the amino group, the saccharide group, or the polyoxyalkylene group-containing group include hydrocarbon such groups, as unsubstituted or substituted alkyl, aryl, and benzyl groups; halogen atoms, such as a fluorine atom, a chlorine atom, and a bromine atom; alkoxy groups; hydroxyl groups; alkoxycarbonyl groups, such as a methoxycarbonyl group and an ethoxycarbonyl group; acyl groups, such as an acetyl group, a propionyl group, and a benzoyl group; cyano groups; and nitro groups.

Examples of the substituent that may be included in the unsubstituted or substituted alkyl group are the same as the groups described above as examples of the substituent. Specific examples thereof include an aryl group and a heteroaryl group.

R^{C1} is preferably a hydrogen atom or an unsubstituted or substituted alkyl group and is more preferably a hydrogen atom. In another preferable aspect, Rel is preferably an unsubstituted or substituted alkyl group, an unsubstituted or substituted amino group, a thiol group, a hydroxyl group, a halogen atom, an unsubstituted or substituted saccharide group, or an unsubstituted or substituted polyoxyalkylene group-containing group.

R^{C2} is preferably a hydrogen atom or an unsubstituted or substituted alkyl group and is more preferably a hydrogen atom.

R^{C3} is preferably a hydrogen atom or an unsubstituted or substituted alkyl group and is more preferably a hydrogen atom.

In Formula (C2), R^{C4} and R^{C5} each independently represent a hydrogen atom, an unsubstituted or substituted alkyl group, an unsubstituted or substituted amino group, a thiol group, a hydroxyl group, a halogen atom, an unsubstituted or substituted saccharide group, an or unsubstituted or substituted polyoxyalkylene group-containing group.

Examples of the groups represented by R^{C4} and R^{C5} are the same as the groups described above as examples of the groups represented by R^{C1} to R^{C3} of Formula (C1).

R^{C4} is preferably a hydrogen atom or an unsubstituted or substituted alkyl group and is more preferably a hydrogen atom.

R^{C5} is preferably a hydrogen atom, an unsubstituted or substituted alkyl group, or an unsubstituted or substituted saccharide group, is more preferably a hydrogen atom or an unsubstituted or substituted saccharide group, and is further preferably a hydrogen atom.

In order to enhance the advantageous effects of the present invention, the content of the first compound is preferably 0.00001% to 0.5% by mass, is more preferably 0.00001% to 0.3% by mass, is further preferably 0.0001% to 0.2% by mass, and is particularly preferably 0.001% to 0.05% by mass of the total mass of the washing liquid.

In order to enhance the advantageous effects of the present invention, the content of the first compound is preferably 0.01% to 60.0% by mass, is more preferably 0.10% to 10.0% by mass, and is further preferably 0.10% to 5.0% by mass of the total solid content of the washing liquid.

Only one type of the first compound may be used alone. Alternatively, two or more types of the first compounds may be used. In the case where two or more types of the first compounds are used, it is preferable that the total content of the first compounds fall within the above range.

### <Second Compound>

The washing liquid includes a second compound. The second compound is at least one compound that is other than the first compound and that is selected from the group consisting of a secondary amine compound, a tertiary amine compound, and a quaternary ammonium compound. The second compound is preferably a tertiary amine compound or a quaternary ammonium compound and is more preferably a tertiary amine compound.

Only one type of the second compound may be used alone. Alternatively, two or more types of the second compounds may be used in combination with one another. The washing liquid preferably includes two or more types of the second compounds and more preferably includes three or more types of the second compounds.

In particular, it is preferable that the washing liquid include two or more types of the second compounds and at least one of the second compounds be a tertiary amine compound. It is more preferable that the washing liquid include three or more types of the second compounds and at least one of the second compounds be a tertiary amine compound.

Furthermore, it is preferable that at least one of the second compounds be a compound selected from the group consisting of the compounds represented by Formulae (A1) and (A2) described below. It is more preferable that at least two of the second compounds be a compound selected from the group consisting of the compounds represented by Formulae (A1) and (A2).

Note that, in the specification, the term “C log P” refers to a value determined by calculating the common logarithm log P of 1-octanol/water partition coefficient P. Publicly known methods and software may be used for calculating C log P. Publicly known literature values (e.g., the values reported in websites, such as http://www.chemspider.com) may also be used. In the present invention, the value determined by drawing the structure using ChemDraw Professional (version 20.1.1.125) produced by PerkinElmer and performing computations using the software is used unless otherwise specified.

In order to enhance the advantageous effects of the present invention, the molecular weight of the second compound is preferably 60 to 300, is more preferably 80 to 170, is further preferably 100 to 160, and is particularly preferably 105 to 150.

### Secondary Amine Compound

The secondary amine compound is a compound that has at least one secondary amino group per molecule. The secondary amine compound may have a primary amino group as an amino group other than a secondary amino group.

Among such secondary amine compounds, 2-(N-methyl)amino-2-methyl-1-propanol, N-(2-hydroxypropyl)ethylenediamine, N-ethylethylenediamine, and N,N′-dimethylethylenediamine are preferable.

### Tertiary Amine Compound

The tertiary amine compound is a compound that has at least one tertiary amino group (>N—) per molecule. The tertiary amine compound may have at least one of a primary amino group or a secondary amino group as an amino group other than a tertiary amino group but preferably has only a tertiary amino group as an amino group (i.e., does not have either a primary amino group or a secondary amino group).

The nitrogen atom included in the tertiary amino group of the tertiary amine compound may be a ring-member atom. In order to enhance the advantageous effects of the present invention, the amine compound preferably does not have a ring structure.

The tertiary amine compound may have a substituent other than a tertiary amino group. Examples of such a substituent include a hydroxyl group.

The tertiary amine compound may have two or more tertiary amino groups. That is, the tertiary amine compound may be a diamine compound or a polyamine compound.

The second compound preferably includes at least one selected from the group consisting of compounds represented by Formulae (A1), (A2), and (A3) and more preferably includes at least one selected from the group consisting of compounds represented by Formulae (A1) and (A2).

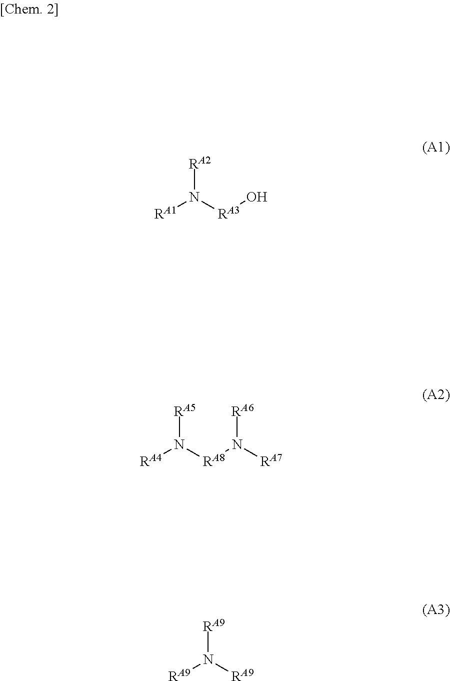

In Formula (A1), R^{A1} and R^{A2} each independently represent a hydrogen atom or an unsubstituted or substituted alkyl group, where at least one of R^{A1} or R^{A2} represents an unsubstituted or substituted alkyl group.

R^{A3} represents an unsubstituted or substituted alkylene group.

TWO of R^{A1} to R^{A3} may be bonded to each other with a single bond or a divalent linking group to form a ring.

R^{A1} and R^{A2} each independently represent a hydrogen atom or an unsubstituted or substituted alkyl group.

The alkyl group may be linear, branched, or cyclic.

The number of carbon atoms included in the alkyl group is preferably 1 to 30, is more preferably 1 to 15, is further preferably 1 to 5, and is particularly preferably 1 to 3.

Examples of the substituent included in the alkyl group include halogen atoms, such as a fluorine atom, a chlorine atom, and a bromine atom; an alkoxy group; a hydroxyl group; acyl groups, such as an acetyl group, a propionyl group, and a benzoyl group; a cyano group; and a nitro group. A hydroxyl group is preferable. In the case where the alkyl group has a hydroxyl group, the number of the hydroxyl groups included in the alkyl group is preferably 1 to 5, is more preferably 1 to 3, and is further preferably 1.

In particular, as R^{A1} and R^{A2}, alkyl groups having 1 to 10 carbon atoms which may have a hydroxyl group are preferable. Alkyl groups having 1 to 3 carbon atoms which may have a hydroxyl group are more preferable. A methyl group, an ethyl group, a propyl group, an isopropyl group, and a 2-hydroxyethyl group are further preferable.

At least one of R^{A1} or R^{A2} represents an unsubstituted or substituted alkyl group. It is preferable that R^{A1} and R^{A2} represent an unsubstituted or substituted alkyl group.

R^{A3} represents an unsubstituted or substituted alkylene group.

The alkylene group may be linear, branched, or cyclic.

The number of carbon atoms included in the alkylene group is preferably 1 to 10, is more preferably 1 to 6, and is further preferably 1 to 4.

Examples of the substituent included in the alkylene group are the same as those of the substituent that may be included in R^{A1} and R^{A2}.

In particular, as R^{A3}, alkylene groups having 1 to 6 carbon atoms are preferable. Alkylene groups having 1 to 4 carbon atoms are more preferable. A methylene group, an ethylene group, a propylene group, a methylethylene group, an ethylethylene group, a 1-methylpropylene group, a 1,1-dimethylethylene group, and a 1,2-dimethylethylene group are further preferable. An ethylene group, a methylethylene group, and a 1,1-dimethylethylene group are particularly preferable.

Two of R^{A1} to R^{A3} may be bonded to each other with a single bond or a divalent linking group to form a ring. The ring may be either monocyclic or polycyclic.

Examples of the divalent linking group include a divalent hydrocarbon group, —O—, and —CO—. An alkylene group is preferable.

Examples of the compound represented by Formula (A1) include 2-(dimethylamino)-2-methyl-1-propanol (DMAMP), N-methyldiethanolamine (MDEA), 2-(diisopropylamino)ethanol, 2-(diethylamino)ethanol (DEAE), 2-(dimethylamino)ethanol (DMAE), N-tert-butyldiethanolamine (t-BDEA), N-ethyldiethanolamine (EDEA), 2-(dibutylamino)ethanol, triethanolamine, 1-[bis(2-hydroxyethyl)amino]-2-propanol, 1-methyl-2-piperidinemethanol, 4-hydroxy-1,2,2,6,6-pentamethylpiperidine (HOPEMP), 1-piperidineethanol, 1-methyl-3-piperidinemethanol, 1-methyl-3-pyrrolidinol, 3-hydroxy-1-methylpiperidine, 2-(N-methyl)amino-2-methyl-1-propanol) (MAMP), diisopropanolamine, dimethanolamine, diethanolamine, 2-(ethylamino)ethanol, 2-(propylamino)ethanol, N-methylethanolamine (N-MEA), N-butylethanolamine, and N-cyclohexylethanolamine.

In Formula (A2), R^{A4} to R^{A7} each independently represent a hydrogen atom or an unsubstituted or substituted alkyl group, where at least one of R^{A4} to R^{A7} represents an unsubstituted or substituted alkyl group.

TWO of R^{A4} to R^{A7} may be bonded to each other with a single bond or a divalent linking group to form a ring. Both of the pair of R^{A4} and R^{A7} and the pair of R^{A5} and R^{A6} may be bonded to each other with a single bond or a divalent linking group to form a ring.

R^{A8} represents an alkylene group that may have a hydroxyl group and a linking group represented by —NR^{Ax}— or —O—, where R^{Ax} represents a hydrogen atom or an alkyl group.

R^{A4} to R^{A7} each independently represent a hydrogen atom or an unsubstituted or substituted alkyl group.

The number of carbon atoms included in the alkyl group is preferably 1 to 30, is more preferably 1 to 15, is further preferably 1 to 6, and is particularly preferably 1 to 3.

Examples of the substituent included in the alkyl group include the substituents that may be included in R^{A1} and R^{A2}.

In particular, as R^{A4} to R^{A7}, alkyl groups having 1 to 3 carbon atoms are preferable. A methyl group, an ethyl group, a propyl group, and an isopropyl group are more preferable. A methyl group is further preferable.

At least one of R^{A4} to R^{A7} represents an unsubstituted or substituted alkyl group. It is preferable that at least two of R^{A4} and R^{A5} represent an unsubstituted or substituted alkyl group. It is more preferable that R^{A4} to R^{A7} represent an unsubstituted or substituted alkyl group.

R^{A8} represents an alkylene group that may have a hydroxyl group and a linking group represented by —NR^{Ax}— or —O—, where R^{Ax} represents a hydrogen atom or an alkyl group.

The number of carbon atoms included in the alkylene group is preferably 1 to 10, is more preferably 1 to 8, and is further preferably 1 to 6.

In the case where the alkylene group has a hydroxyl group, the number of hydroxyl groups included in the alkylene group is preferably 1 to 5, is more preferably 1 to 3, and is further preferably 1.

The number of the linking groups represented by —NR^{Ax}— which is included in the alkylene group is preferably 0 to 3 and is more preferably 0 or 1.

The number of the linking groups represented by —O— which is included in the alkylene group is preferably 0 to 3 and is more preferably 0 or 1.

R^{Ax} is preferably a hydrogen atom or an alkyl group having 1 to 3 carbon atoms, is more preferably a hydrogen atom, a methyl group, an ethyl group, or an isopropyl group, and is more preferably a methyl group.

Two of R^{A4} to R^{A7} may be bonded to each other with a single bond or a divalent linking group to form a ring. The ring may be either monocyclic or polycyclic.

Examples of the divalent linking group include a divalent hydrocarbon group, —O—, and —CO—. An alkylene group is preferable.

Examples of the compound represented by Formula (A2) include N,N,N′,N″,N″-pentamethyldiethylenetriamine (PMDTA), tetramethyl-1,3-diaminobutane, tetramethyl-1,6-diaminohexane, N,N-diisopropylethylenediamine (DIPEN), N,N-dimethylethylenediamine (DMEN), N,N-diethylethylenediamine, tetramethyl-1,3-diaminopropane, pentamethyldipropylenetriamine, N,N′-dimethylethylenediamine N-(2-(NN′-DMEN), hydroxypropyl)ethylenediamine (HPEN), N-ethylethylenediamine (EEN), 1,4-bis(2-hydroxyethyl)piperazine (BHEP), 1,4-bis(2-aminoethyl)piperazine (BAEP), 1,4-bis(3-aminopropyl)piperazine (BAPP), and 1,4-diazabicyclo[2.2.2]octane (DABCO).

In Formula (A3), R^{A9}'s each independently represent an alkyl group. The alkyl group may be linear, branched, or cyclic.

The number of carbon atoms included in the alkyl group is preferably 1 to 30, is more preferably 1 to 15, is further preferably 1 to 5, and is particularly preferably 1 to 3.

Examples of the compound represented by Formula (A3) include trimethylamine (TMA) and triethylamine (TEA).

### Quaternary Ammonium Compound

The quaternary ammonium compound is not limited and may be any compound that quaternary ammonium cation portion constituted by a nitrogen atom and four hydrocarbon groups bonded to the nitrogen atom.

The quaternary ammonium compound may also be a compound having a quaternary ammonium cation portion constituted by a pyridine ring and hydrocarbon groups (e.g., alkyl or aryl groups) bonded to the nitrogen atom of the pyridine ring, such an as alkylpyridinium.

The number of carbon atoms included in the quaternary ammonium cation portion of the quaternary ammonium compound is preferably 4 to 20 and is more preferably 5 to 15. Note that the term “number of carbon atoms” refers to the total number of carbon atoms included in the quaternary ammonium cation portion; the number of carbon atoms included in the anion forming a salt is not included.

Examples of the anion portion corresponding to the quaternary ammonium cation portion include, but are not limited to, a hydroxide ion, a halide ion (e.g., a chloride ion, a bromide ion, a fluoride ion, or an iodide ion), an acetate ion, a carbonate ion, and a sulfate ion.

In particular, the quaternary ammonium salt represented by Formula (a) below is preferably included in the quaternary ammonium compound.

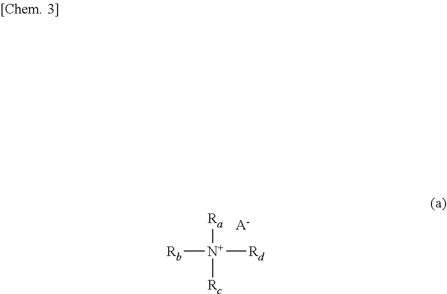

In Formula (a), Rₐ to R_{d} each independently represent an unsubstituted or substituted alkyl group.

The alkyl group may be linear or branched and is preferably linear. The number of carbon atoms included in the alkyl group portion of the alkyl group is preferably 1 to 10, is more preferably 1 to 6, is further preferably 1 to 4, and is particularly preferably 1 or 2.

Specific examples of the alkyl group include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, and a hexadecyl group. Examples of the substituent include a hydroxyl group and a phenyl group. Examples of the substituted alkyl group include a 2-hydroxyethyl group, a 2-hydroxypropyl group, and a benzyl group. The methylene group constituting the alkyl group may be replaced with a divalent substituent, such as —O—.

The total number of carbon atoms included in Rₐ to R_{d} is preferably, but not limited to, 4 to 20 and is more preferably 5 to 15. Two unsubstituted or substituted alkyl groups selected from Rₐ to R_{d} may be bonded to each other to form a ring.

In Formula (a), A⁻ represents a monovalent anion.

Examples of the monovalent anion represented by A⁻ include F⁻, Cl⁻, Br⁻, OH⁻, NO₃⁻, CH₃COO⁻, and CH₃CH₂SO₄⁻. F⁻, Cl⁻, Br⁻, and OH⁻ are preferable. Cl⁻ and OH⁻ are more preferable. OH⁻ is further preferable.

Examples of the quaternary ammonium compound represented by Formula (a) include a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a dodecyltrimethylammonium salt, a trimethyltetradecylammonium salt, a hexadecyltrimethylammonium salt, a benzyltrimethylammonium salt, a benzyltriethylammonium salt, a (2-hydroxyethyl)trimethylammonium salt (also referred to as “choline”), a triethyl(2-hydroxyethyl)ammonium salt, a diethyl bis(2-hydroxyethyl)ammonium salt, an ethyl tris(2-hydroxyethyl)ammonium salt, and a tris(2-hydroxyethyl)methylammonium salt.

In particular, it is preferable that the quaternary ammonium compound include at least one selected from the group consisting of a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt, and a triethyl(2-hydroxyethyl)ammonium salt.

The anion included in the above salt is preferably F⁻, Cl⁻, Br⁻, or OH⁻, is more preferably Cl⁻ or OH⁻, and is further preferably OH⁻.

The molecular weight of the quaternary ammonium compound is preferably 90 to 1000, is more preferably 90 to 500, is further preferably 90 to 300, and is particularly preferably 90 to 200. Only one type of the quaternary ammonium compound may be used alone. Alternatively, two or more types of the quaternary ammonium compounds may be used in combination.

The content of the second compound is preferably 0.001% to 50.0% by mass, is more preferably 0.01% to 30.0% by mass, is further preferably 0.03% to 10.0% by mass, and is particularly preferably 0.03% to 3.0% by mass of the total mass of the washing liquid in order to enhance the advantageous effects of the present invention.

The content of the second compound is preferably 40.0% to 99.99% by mass, is more preferably 70.0% to 99.99% by mass, and is further preferably 75.0% to 98.0% by mass of the total solid content of the washing liquid in order to enhance the advantageous effects of the present invention.

The ratio of the content of the nonionic surfactant relative to the total mass of the polishing fluid to the content of the second compound relative to the total mass of the washing liquid is preferably 0.0010 to 15.5, is more preferably 0.0035 to 3.5, and is further preferably 0.0035 to 1.0.

For example, in the case where the content of the second compound relative to the total mass of the washing liquid is 0.18 by mass and the content of the nonionic surfactant relative to the total mass of the polishing fluid is 0.05% by mass, the above ratio is calculated as (0.05×10⁻²)/(0.1×10⁻²)=0.50.

The mass ratio of the content of the first compound to the content of the second compound (Content of first compound/Content of second compound) is preferably 0.10 to 7000.00, is more preferably 2.50 to 1000.00, is further preferably 10.00 to 1000.00, and is particularly preferably 25.00 to 100.00.

Only one type of the second compound may be used alone. Alternatively, two or more types of the second compounds may be used. In the case where two or more types of the second compounds are used, it is preferable that the total content of the second compounds fall within the above range.

The washing liquid may include a constituent other than any of the above-described constituents (i.e., the first and second compounds).

Details of the other constituents are described below.

### <Other Amine Compound>

The washing liquid may include an amine compound other than the first or second compound (hereinafter, such an amine compound is also referred to as “other amine compound”).

The other amine compound may have a substituent other than an amino group. Examples of the substituent include a hydroxyl group.

Examples of the other amine compound include an amine compound having only a primary amino group (—NH₂) as an amino group (i.e., a primary amine compound). The primary amine compound may be either a monoamine compound or a polyamine compound and is preferably a monoamine compound.

The monoamine compound is preferably a monoamine compound having a hydroxyl group. Examples thereof include monoethanolamine (MEA), diisopropanolamine, dimethanolamine, diethanolamine, 2-(ethylamino)ethanol, 2-(propylamino)ethanol, N-methylethanolamine (N-MEA), 2-amino-2-methyl-1-propanol (AMP), 2-methyl-2-(methylamino) propan-1-ol (MAMP), N-phenyldiethanolamine (Ph-DEA), N-butylethanolamine, and N-cyclohexylethanolamine.

Examples of the polyamine compound include ethylenediamine (EDA), 1,3-propanediamine (PDA), 1,2-propanediamine, 1,3-butanediamine, and 1,4-butanediamine.

The total content of the other amine compounds is preferably 0.0001% to 20.0% by mass, is more preferably 0.0005% to 10.0% by mass, is further preferably 0.001% to 5.0% by mass, and is particularly preferably 0.001% to 0.1% by mass of the total mass of the washing liquid in order to enhance the advantageous effects of the present invention.

The total content of the other amine compounds is preferably 1.0% to 50.0% by mass, is more preferably 1.0% to 30.0% by mass, and is further preferably 3.0% to 30.0% by mass of the total solid content of the washing liquid in order to enhance the advantageous effects of the present invention.

Only one type of the other amine compound may be used alone. Alternatively, two or more types of the other amine compounds may be used. In the case where two or more types of the other amine compounds are used, it is preferable that the total content of the other amine compounds fall within the above range.

### <Water>

The washing liquid may include water as a solvent.

The water included in the washing liquid may be any type of water that does not adversely affect semiconductor substrates. Distilled water, deionized (DI) water, and pure water (ultrapure water) may be used. Pure water (ultrapure water) is preferable because it hardly contains impurities and the negative impacts thereof on semiconductor substrates in the production of the semiconductor substrates are smaller.

The content of the water may be the balance of the constituents that may be included in the washing liquid.

The content of the water is preferably 1.0% by mass or more, is more preferably 30.0% by mass or more, is further preferably 60.0% by mass or more, and is particularly preferably 80.0% by mass or more of the total mass of the washing liquid. The upper limit is preferably 99.9999% by mass or less, is more preferably 99.99% by mass or less, and is further preferably 99.97% by mass or less in order to enhance the advantageous effects of the present invention.

### <Organic Acid>

The washing liquid may include an organic acid. The washing liquid preferably includes an organic acid in order to enhance the advantageous effects of the present invention. The organic acid is a compound other than any of the first and second compounds described above.

Examples of the organic acid include carboxylic acids, such as an aliphatic carboxylic acid and an aromatic carboxylic acid, and a phosphonic acid.

The organic acid may be in the form of a salt. The salt is an inorganic salt or the like.

Examples of the aliphatic carboxylic acid include succinic acid, tartaric acid, maleic acid, oxalic acid, malonic acid, glutaric acid, adipic acid, pimelic acid, sebacic acid, formic acid, citric acid, malic acid, glycolic acid, gluconic acid, heptonic acid, and lactic acid.

Examples of the aromatic carboxylic acid include phenyllactic acid, hydroxyphenyllactic acid, phenylsuccinic acid, phthalic acid, isophthalic acid, terephthalic acid, gallic acid, trimellitic acid, mellitic acid, and cinnamic acid.

As a phosphonic acid, for example, the compounds described in Paragraphs [0026] to [0036] of WO2018/020878A and the compounds (i.e., (co)polymers) described in Paragraphs [0031] to [0046] of WO2018/030006A may be used. The contents of the above patent documents are incorporated herein.

The content of the organic acid is preferably 0.1 ppm by mass to 5.0% by mass, is more preferably 1 ppm by mass to 1.0% by mass, and is further preferably 10 ppm by mass to 0.3% by mass of the total mass of the washing liquid.

The content of the organic acid is preferably 0.1% to 10.0% by mass, is more preferably 0.5% to 5.0% by mass, and is further preferably 1.0% to 3.0% by mass of the total solid content of the washing liquid.

Only one type of the organic acid may be used alone. Alternatively, two or more types of the organic acids may be used. In the case where two or more types of the organic acids are used, it is preferable that the total content of the organic acids fall within the above range.

### <Other Constituent>

The washing liquid may include at least one constituent selected from the group consisting of a surfactant, a pH-controlling agent, an organic solvent, a polymer, a polyhydroxy compound having a molecular weight of 500 or more, and an oxidizing agent, which is other than any of the above-described compounds.

The other constituents are described below.

### Surfactant

The surfactant is not limited and may be any compound that has a hydrophilic group and a hydrophobic group (i.e., a lipophilic group) in one molecule. Examples thereof include a nonionic surfactant and an anionic surfactant.

The surfactant commonly has at least one hydrophobic group selected from the group consisting of an aliphatic hydrocarbon group, an aromatic hydrocarbon group, and a group that is a combination of these groups.

The number of carbon atoms included in the entire surfactant is preferably 16 to 100.

Examples of the nonionic surfactant include an ester-type nonionic surfactant, an ether-type nonionic surfactant, and an ester ether-type nonionic surfactant. An ether-type nonionic surfactant is preferable.

For example, the compounds described in Paragraph of WO2022/044893A as examples may also be used as a nonionic surfactant. The contents of the above patent document are incorporated herein.

Examples of the anionic surfactant include a phosphoric acid ester-based surfactant having a phosphoric acid ester group, a sulfonic acid-based surfactant having a sulfo group, a phosphonic acid-based surfactant having a phosphonic acid group, a carboxylic acid-based surfactant having a carboxyl group, and a sulfuric acid ester-based surfactant having a sulfuric acid ester group.

For example, the compounds described in Paragraphs [0116] to [0123] of WO2022/044893A as examples may also be used as an anionic surfactant. The contents of the above patent document are incorporated herein.

Only one type of the surfactant may be used alone. Alternatively, two or more types of the surfactants may be used in combination. The content of the surfactant is preferably 0.0001% to 5.00% by mass, is more preferably 0.0005% to 1.00% by mass, and is further preferably 0.001% to 0.10% by mass of the total mass of the washing liquid in order to enhance the performance of the washing liquid.

The content of the surfactant is preferably 0.1% to 50.0% by mass, is more preferably 0.5% to 30.0% by mass, and is further preferably 1.0% to 10.0% by mass of the total solid content of the washing liquid in order to enhance the performance of the washing liquid.

Only one type of the surfactant may be used alone. Alternatively, two or more types of the surfactants may be used. In the case where two or more types of the surfactants are used, it is preferable that the total content of the surfactants fall within the above range.

pH-Controlling Agent

The washing liquid may include a pH-controlling agent for adjusting and maintaining the pH of the washing liquid. The pH-controlling agent includes a basic compound and an acidic compound which are other than any of the compounds that may be included in the washing liquid. Note that the pH of the washing liquid may be adjusted by changing the amounts of the above constituents added.

The basic and acidic compounds that may be used as a pH-controlling agent are the same as in the detailed description of the pH-controlling agent that may be included in the polishing fluid.

The content of the pH-controlling agent may be selected in accordance with the types and amounts of the other constituents and the intended pH of the washing liquid. For example, the content of the pH-controlling agent is preferably 0.0001% to 10% by mass and is more preferably 0.001% to 8% by mass of the total mass of the washing liquid.

The content of the pH-controlling agent is preferably 0.01% to 80% by mass and is more preferably 0.1% to 60% by mass of the total solid content of the washing liquid.

Only one type of the pH-controlling agent may be used alone. Alternatively, two or more types of the pH-controlling agents may be used. In the case where two or more types of the pH-controlling agents are used, it is preferable that the total content of the pH-controlling agents fall within the above range.

### Organic Solvent

The washing liquid may include an organic solvent.

Examples of the organic solvent include publicly known organic solvents, such as an alcohol-based solvent, a glycol-based solvent, a glycol ether-based solvent, and a ketone-based solvent. The organic solvent is preferably mixed with water at a predetermined ratio.

For example, the compounds described in Paragraphs to of WO2022/044893A may be used as an organic solvent. The contents of the above patent document are incorporated herein.

### Polymer

Examples of the polymer include a water-soluble polymer.

The term “water-soluble polymer” refers to a compound that includes two or more structural units joined to one another with a covalent bond in a linear or net-like pattern, wherein the mass of the compound soluble in 100 g of water at 20 °C is 0.1 g or more.

For example, the water-soluble polymers described in Paragraphs [0043] to [0047] of JP2016-171294A may be used as a polymer. The contents of the above patent document are incorporated herein.

The molecular weight of the polymer (in the case where the polymer has a molecular-weight distribution, the weight-average molecular weight of the polymer) is preferably 300 or more, is more preferably more than 600, is further preferably 1000 or more, is particularly preferably more than 1000, and is most preferably 2000 or more. The upper limit is preferably 1500000 or less and is more preferably 1000000 or less.

### Polyhydroxy Compound Having Molecular Weight of 500 or More

For example, the compounds described in Paragraphs [0101] and [0102] of WO2022/014287A may be used as a polyhydroxy compound. The contents of the above patent document are incorporated herein.

### Oxidizing Agent

Examples of the oxidizing agent include peroxides, persulfides (e.g., a monopersulfide and a dipersulfide), percarbonic acid salts, acids thereof, and salts thereof.

Examples of the oxidizing agent include halide oxides (e.g., iodic acid, periodic acids, such as metaperiodic acid and orthoperiodic acid, and salts thereof), a perboric acid, a perborate, a cerium compound, and a ferricyanide (e.g., potassium ferricyanide).

### (Physical Properties of Washing Liquid)

Details of the properties of the washing liquid are described below.

<pH>

The washing liquid may be either alkaline or acidic.

In order to enhance the advantageous effects of the present invention, the pH of the washing liquid is preferably 7.0 to 14.0, is more preferably 9.0 to 14.0, is further preferably 10.0 to 14.0, and is particularly preferably 10.0 to 13.5.

The pH of the washing liquid can be adjusted using the pH-controlling agent described above.

The pH of the washing liquid can be measured with a publicly known pH meter by a method conforming to JIS Z 8802-1984. The measurement of pH is done at 25 °C.

### <Metal Content>

The contents (measured as ionic concentrations) of metals (i.e., metal elements such as Fe, Co, Na, Cu, Mg, Mn, Li, Al, Cr, Ni, Zn, Sn, and Ag) included in the washing liquid as impurities are each preferably 5 ppm by mass or less and more preferably 1 ppm by mass or less. Since it is considered that washing liquids having further high purities are required in the production of leading-edge semiconductor elements, the above metal content is further preferably less than 1 ppm by mass, that is, on the order of parts per billion by mass or less. The above metal content is particularly preferably 100 ppb by mass or less and is most preferably less than 10 ppb by mass. The lower limit is preferably 0.

For reducing the above metal content, for example, the raw materials used for producing the washing liquid may be subjected to a purification treatment, such as distillation or filtering using an ion-exchange resin or a filter. In another case, the washing liquid may be subjected to the purification treatment after the production of the washing liquid.

Another example of the method for reducing the metal content is to use a container from which the impurities described below are not eluted in large amounts as a container for accommodating the raw materials or the washing liquid produced. Alternatively, for example, the inner walls of pipes may be lined with a fluororesin in order to reduce the likelihood of the metal constituents eluting from the pipes or the like during the production of the washing liquid.

### <Coarse Particles>

The washing liquid may include coarse particles, but the content of the coarse particles is preferably low.

The term “coarse particles” used herein refers to particles having a diameter (particle size) of 0.03 μm or more when the shape of the particles is considered spherical.

The coarse particles included in the washing liquid are particles of dust, organic and inorganic solid substances, and the like included in the raw materials as impurities and particles of dust, organic and inorganic solid substances, and the like that enter the washing liquid as contaminants during the preparation of the washing liquid, which are not finally dissolved in the washing liquid and present in the form of particles.

As for the content of the coarse particles in the washing liquid, the number of particles having a size of 0.1 μm or more is preferably 10000 or less and is more preferably 5000 or less per milliliter of the washing liquid. The lower limit is preferably 0 or more and is more preferably 0.01 or more per milliliter of the washing liquid.

The content of the coarse particles in the washing liquid can be measured in a liquid phase using a commercial light scattering liquid borne particle counting device with a laser light source. Examples of the method for removing the coarse particles include a purification treatment, such as filtering, described below.

### (Method for Producing Washing Liquid)

The washing liquid can be produced using a publicly known method. The method for producing the washing liquid is described in detail below.

### <Liquid Preparation Step>

The washing liquid can be produced by, for example, mixing the above-described constituents with one another.

The washing liquid is produced by, for example, adding the above-described constituents to a container including purified water, stirring the resulting liquid mixture, and adding a pH-controlling agent to the liquid mixture as needed to adjust the pH of the liquid mixture. When water and the above constituents are added to the container, they may be added in one batch or a plurality of batches in small amounts.

As a stirring device or method used in the preparation of the washing liquid, stirring devices and methods publicly known as a stirrer or disperser may be used. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

### <Refinement>

It is preferable to subject one or more of the raw materials used for preparing the washing liquid to a purification treatment before use. Examples of the purification treatment include publicly known methods such as distillation, ion-exchange, and filtering.

As for the degree of purification, it is preferable to perform purification until the purity of the raw material reaches 99% by mass or more. It is more preferable to perform purification until the purity of the stock solution reaches 99.9% by mass or more. The upper limit is preferably 99.9999% by mass or less.

Examples of the purification treatment method include a method of passing the raw material through an ion-exchange resin, a reverse osmosis (RO) membrane, or the like, distillation of the raw material, and the filtering described below.

A plurality of the purification methods may be performed in combination as a purification treatment. For example, after the raw material has been passed through an RO membrane as primary purification, it may be passed through a purification device composed of a cation-exchange resin, an anion-exchange resin, or a mixed-bed ion-exchange resin as secondary purification.

The purification treatment may be performed a plurality of times.

The filter used for filtering is not limited and may be any filter that has been used for filtering or the like. Examples thereof include filters composed of a fluororesin, such as polytetrafluoroethylene (PTFE) or a tetrafluoroethylene perfluoro alkyl vinyl ether copolymer (PFA); a polyamide resin, such as nylon; and a polyolefin resin (including high-density or ultrahigh-molecular-weight polyolefin resin), such as polyethylene or polypropylene (PP). Among these materials, a material selected from the group consisting of polyethylene, polypropylene (including high-density polypropylene), a fluororesin (including PTFE and PFA), and a polyamide resin (including nylon) is preferable. A filter composed of a fluororesin is more preferable. Filtering the raw material through a filter composed of any of the above materials enables foreign matter having a high polarity, which is likely to cause defects, to be removed effectively.

### <Container>

The washing liquid (which may be a diluted washing liquid described below) may be charged into a container for storage and transportation when corrosive properties or the like do not pose a problem.

The container is preferably a container for semiconductors which has a high cleanliness class and in which the elution of impurities from the inner wall of the container to the liquid is suppressed. Examples of such a container include various containers commercially available as containers for semiconductor washing liquids. Examples thereof include, but are not limited to, “Clean Bottle” series produced by AICELLO CORPORATION and “Pure Bottle” produced by KODAMA PLASTICS Co., Ltd.

The containers described in Paragraphs [0121] to [0124] of WO2022/004217A as examples may also be used as a container. The contents of the above patent document are incorporated herein.

It is preferable to clean the inside of the container before the washing liquid is charged thereinto. It is preferable to reduce the content of metal impurities in the liquid used for cleaning. After production, the washing liquid may be bottled in a container, such as a gallon bottle or a quart bottle, for transportation or storage.

In order to prevent the degradation of the constituents of the washing liquid during storage, the inside of the container may be purged with an inert gas (e.g., a nitrogen or argon gas) having a purity of 99.99995% by volume or more. A gas having a low moisture content is particularly preferable. The transportation and storage may be done at normal temperature. In order to prevent the degradation, the temperature may be controlled to fall within the range of −20 °C to 20 °C.

### <Cleanroom>

Handling such as the production of the washing liquid, opening and cleaning of the container, and charging of the washing liquid, treatment and analysis, and measurement are preferably all done in a cleanroom. The cleanroom preferably satisfies the standard 14644-1 for cleanroom. The cleanroom preferably satisfies any of International Organization for Standardization (ISO) class 1, 2, 3, or 4, more preferably satisfies ISO class 1 or 2, and further preferably satisfies ISO class 1.

### <Dilution Step>

The washing liquid may be used for the treatment of the processing object as a diluted washing liquid after being subjected to a dilution step, in which the washing liquid is diluted with a diluent, such as water.

Note that the diluted washing liquid is also one of the modes of the washing liquid when the diluted washing liquid satisfies the requirements of the present invention.

It is preferable to subject the diluent used in the dilution step to a purification treatment before use. It is more preferable to subject the diluted washing liquid prepared in the dilution step to a purification treatment.

Examples of the purification treatment include the ion component reduction treatment using an ion-exchange resin, an RO membrane, or the like and the removal of foreign matter by filtering, which are described above as a purification treatment for the washing liquid. It is preferable to perform any of the above treatments.

The dilution factor at which the washing liquid is diluted in the dilution step may be adjusted appropriately in accordance with the types and contents of the constituents and the object that is to be processed. The ratio (i.e., dilution factor) of the diluted washing liquid to the washing liquid that has not been diluted is preferably 10 to 10000 times, is more preferably 20 to 3000 times, is further preferably 50 to 1000 times, and is particularly preferably 30 to 150 times in terms of mass ratio or volume ratio (volume ratio at 23 °C).

The washing liquid is preferably diluted with water in order to enhance the cleaning properties.

The change in pH caused by dilution (the difference between the pH of the washing liquid that has not been diluted and the pH of the diluted washing liquid) is preferably 2.0 or less, is more preferably 1.8 or less, and is further preferably 1.5 or less. The pH of the washing liquid that has not been diluted and the pH of the diluted washing liquid preferably fall within the preferable range described above.

The specific method for conducting the dilution step in which the washing liquid is diluted may be performed in conformity with the step for preparing the above washing liquid. As for the stirring device and method used in the dilution step, publicly known stirring devices described in the step for preparing the above washing liquid may be used.

### <<Method for Producing Kit>>

The method for producing the kit is not limited. The kit may be produced by, for example, after the production of the polishing fluid and the washing liquid described above, charging them into different vessels. Examples of the vessel include the container for the washing liquid, which is described above.

### <<Method for Producing Semiconductor Device>>

The kit according to the present invention is used for chemical mechanical polishing of a processing object and cleaning of the processing object that has been subjected to the chemical mechanical polishing. In particular, the kit may be suitably used for the method for producing a semiconductor device.

Examples of the method for producing a semiconductor device include, but are not limited to, a method including a step 1 of subjecting a processing object to chemical mechanical polishing using a polishing fluid and a step 2 of, subsequent to the step 1, cleaning the processing object that has been subjected to the chemical mechanical polishing with a washing liquid.

### <Step 1>

Step 1 is a step of subjecting a processing object to chemical mechanical polishing using the above-described polishing fluid. Examples of the object that is to be processed with the washing liquid include a processing object including a metal. The processing object is preferably a semiconductor substrate including a metal.

In the case where the semiconductor substrate includes a metal, for example, any of the front, rear, and side surfaces, grooves, and the like of the semiconductor substrate may include the metal. The expression “the semiconductor substrate includes a metal” refers to not only the case where the metal is disposed directly on the surface of the semiconductor substrate but also the case where the metal is disposed above the semiconductor substrate with another layer interposed therebetween.

Examples of the metal include at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), and iridium (Ir). Cu, Co, and Ru are preferable. Cu is more preferable. That is, the processing object is preferably a processing object including Cu.

The metal may be any substance that includes a metal (metal atom). Examples of the metal include a simple substance of the metal M and an alloy containing the metal M.

The processing object may have various layers and/or structures as needed in addition to the above. For example, in the case where the processing object is a semiconductor substrate, the processing object may have the following members: a barrier layer (e.g., a layer including a barrier metal, such as titanium (Ti), titanium nitride (TiN), tantalum (Ta), tantalum nitride (TaN), cobalt (Co), or ruthenium (Ru)), a metal wire, an oxide film, a gate electrode, a source electrode, a drain electrode, an insulating layer, a ferromagnetic layer, an integrated circuit structure, and/or a non-magnetic layer.

The type of the substrate included in the processing object is not limited. Examples thereof include the following various substrates: a semiconductor wafer, a glass substrate for photomasks, a glass substrate for liquid crystal displays, a glass substrate for plasma displays, a substrate for field emission displays (FEDs), a substrate for optical disks, a substrate for magnetic disks, and a substrate for magneto-optical disks.

The size, thickness, shape, and layer structure of the substrate are not limited and may be selected appropriately as needed.

Examples of the wafer constituting the semiconductor substrate include wafers composed of a silicone-containing material, such as a silicon (Si) wafer, a silicon carbide (SiC) wafer, and a silicon-containing resin-based wafer (glass epoxy wafer); a gallium phosphide (GaP) wafer; a gallium arsenide (GaAs) wafer; and an indium phosphide (InP) wafer.

Examples of the silicon wafer include an n-type silicon wafer produced by doping a silicon wafer with a pentavalent atom (e.g., phosphorus (P), arsenic (As), or antimony (Sb)); and a p-type silicon wafer produced by doping a silicon wafer with a trivalent atom (e.g., boron (B) or gallium (Ga)). Examples of the silicon constituting the silicon wafer include amorphous silicon, single-crystal silicon, polycrystalline silicon, and polysilicon.

Among these, wafers composed of a silicone-containing material, such as a silicon wafer, a silicon carbide wafer, and a silicon-containing resin-based wafer (glass epoxy wafer), are preferable.

Examples of the insulation film include silicon oxide films (e.g., a silicon dioxide (SiO₂) film and a tetraethyl orthosilicate (Si(OC₂H₅)₄) film (TEOS film)); silicon nitride films (e.g., silicon nitride (Si₃N₄) and silicon nitride carbide (SiNC)), and low-dielectric constant (Low-k) films (e.g., a carbon-doped silicon oxide (SiOC) film and a silicon carbide (SiC) film). Low-dielectric constant (Low-k) films are preferable.

The metal wire film is preferably a copper-containing film, a cobalt-containing film, or a ruthenium-containing film. Examples of the copper-containing film include a wire film (copper wire film) composed only of metal copper and a wire film (copper alloy wire film) composed of an alloy including metal copper and another metal.

Examples of the copper alloy wire film include a wire film composed of an alloy including one or more metals selected from the group consisting of Al, Ti, Cr, Mn, Ta, and W and copper. Specific examples thereof include a copper-aluminum alloy wire film (CuAl alloy wire film), a copper-titanium alloy wire film (CuTi alloy wire film), a copper-chromium alloy wire film (CuCr alloy wire film), a copper-manganese alloy wire film (CuMn alloy wire film), a copper-tantalum alloy wire film (CuTa alloy wire film), and a copper-tungsten alloy wire film (CuW alloy wire film).

Examples of the cobalt-containing film include a metal film (cobalt metal film) composed only of metal cobalt and a metal film (cobalt alloy metal film) composed of an alloy of metal cobalt with another metal.

Examples of the cobalt alloy metal film include a metal film composed of an alloy of one or more metals selected from the group consisting of Ti, Cr, Fe, Ni, Mo, Pd, Ta, and W with cobalt. Specific examples thereof include a cobalt-titanium alloy metal film (CoTi alloy metal film), a cobalt-chromium alloy metal film (CoCr alloy metal film), a cobalt-iron alloy metal film (CoFe alloy metal film), a cobalt-nickel alloy metal film (CoNi alloy metal film), a cobalt-molybdenum alloy metal film (CoMo alloy metal film), a cobalt-palladium alloy metal film (CoPd alloy metal film), a cobalt-tantalum alloy metal film (CoTa alloy metal film), and a cobalt-tungsten alloy metal film. (CoW alloy metal film).

The washing liquid is useful for substrates having a cobalt-containing film. Among cobalt-containing films, a cobalt metal film is commonly used as a wire film, while a cobalt alloy metal film is commonly used as a barrier metal.

Examples of the ruthenium-containing film include a metal film (ruthenium metal film) composed only of metal ruthenium and a metal film (ruthenium alloy metal film) composed of an alloy of metal ruthenium with another metal. The ruthenium-containing film is commonly used as a barrier metal.

The method for forming the above insulation film, the copper-containing film, the cobalt-containing film, or the ruthenium-containing film on the wafer constituting the semiconductor substrate is not limited and may be any method commonly employed in the field.

The method for forming an insulation film is, for example, a method in which a wafer constituting a semiconductor substrate is heat-treated in the presence of an oxygen gas in order to from a silicon oxide film and, subsequently, gases of silane and ammonia are charged in order to form a silicon nitride film by chemical vapor deposition (CVD).

The method for forming the copper-containing film, the cobalt-containing film, or the ruthenium-containing film is, for example, a method in which a circuit is formed on a wafer having the insulation film formed thereon by a publicly known method, such as a resist, and a copper-containing film, a cobalt-containing film, or a ruthenium-containing film is subsequently formed by plating, CVD, or the like.

Step 1 is a step of subjecting a processing object to chemical mechanical polishing (CMP) using the polishing fluid described above.

The CMP process may be performed by moving the processing object and a polish pad attached to the polishing platen relative to each other with the polishing surface of the processing object being brought into contact with the polish pad, while feeding the polishing fluid to the polish pad.

The CMP process may be performed using a publicly known chemical mechanical polishing device (hereinafter, also referred to as “CMP device).

Examples of the CMP device include a common CMP device that includes a holder that holds a processing object having a polishing surface and a polishing platen to which a polish pad is attached (including a motor or the like the rotation speed of which is adjustable). The polish pad is not limited; common nonwoven fabrics, a polyurethane foam, a porous fluororesin, and the like may be used.

The polish pressure in the CMP process is commonly set to 10 to 980 hPa. In order to reduce the formation of flaw-like defects and irregularities in the polishing surface, the polish pressure is preferably 30 to 250 hPa and is more preferably 65 to 140 hPa. Note that the term “polish pressure” used herein refers to the pressure that acts on a portion of the polishing surface with which the polish pad is in contact.

The rotation speed of the polishing platen used in the CMP process is commonly set to 10 to 400 rpm, is preferably 50 to 200 rpm, and is more preferably 60 to 160 rpm.

In order to move the processing object and the polish pad relative to each other, the holder may be rotated and/or shaken, the polishing platen may be revolved and rotated, or a belt-like polish pad may be moved in one direction along the long-length direction in a linear manner. Note that the holder may be fixed, rotated, or shaken. The polishing method may be selected appropriately in accordance with the polishing surface and/or the polishing device.

In the CMP process, it is preferable to continuously feed the polishing fluid to the polish pad disposed on the polishing platen with a pump or the like while the polishing surface is polished. The amount of the polishing fluid fed is not limited; it is preferable that the surface of the polish pad is consistently covered with the polishing fluid.

The feeding speed of the polishing fluid is preferably 10 to 1000 mL/min and is more preferably 170 to 500 mL/min in order to reduce the formation of flaw-like defects and irregularities in the polishing surface.

The CMP process may be performed only once or two or more times. In the case where the CMP process is performed two or more times, the polishing conditions, such as the polish pressure, the polishing rate, and the feeding speed of the polishing fluid, and the polishing fluid used may be, but are not necessarily, changed in each time.

### <Step 2>

Step 2 is a step of, subsequent to Step 1, cleaning the processing object, which has been subjected to chemical mechanical polishing, with the above-described washing liquid.

The above cleaning treatment may be performed by any of the publicly known methods. Examples thereof include a method in which the processing object is brought into contact with the washing liquid.

Examples of the method in which the processing object is brought into contact with the washing liquid include, but are not limited to, a method in which the processing object is immersed in the washing liquid charged in a tank, a method in which the washing liquid is splayed onto the processing object, and a method in which the washing liquid is passed over the processing object, and a combination of these methods. The above method may be selected appropriately in accordance with the intended purpose. Furthermore, the methods commonly used in this field may be used as needed. For example, a method in which, while the washing liquid is fed, a cleaning member, such as a brush, is brought into physical contact with the surface of the processing object in order to remove residues or the like, that is, scrub cleaning; and a spin (drop) method in which the washing liquid is dropped to the processing object while the processing object is rotated may also be used. In the above immersion method, the processing object immersed in the washing liquid is preferably subjected to an ultrasonic treatment in order to further reduce the amount of impurities that remain on the surface of the processing object.

The processing object may be brought into contact with the washing liquid only once or two or more times. In the case where they are brought into contact with each other two or more times, the same method may be repeated or different methods may be performed in combination.

The cleaning treatment may be performed in either a single-wafer mode or a batch mode.

The term “single-wafer mode” commonly refers to a method in which processing objects are treated one by one, while the term “batch mode” commonly refers to a method in which a plurality of processing objects are treated at a time.

The temperature of the washing liquid is not limited and may be any temperature commonly employed in this field. Although cleaning is commonly performed at room temperature (about 25 °C), the above temperature may be selected as needed in order to enhance the defect removal performance and prevent damage to members. The temperature of the washing liquid is preferably, for example, 10 °C to 60 °C and is more preferably 15 °C to 50 °C.

The amount of time during which the processing object is brought into contact with the washing liquid may be changed appropriately in accordance with the types and contents of the constituents of the washing liquid, the target to which the washing liquid is used, and the purpose for which the washing liquid is used. Practically, the above time is preferably 10 to 120 seconds, is more preferably 20 to 90 seconds, and is further preferably 30 to 60 seconds.

The amount of the washing liquid fed (i.e., the feeding speed of the washing liquid) is preferably 50 to 5000 mL/min and is more preferably 500 to 2000 mL/min.

In order to enhance the performance of the washing liquid achieved when the processing object is brought into contact with the washing liquid, a mechanical stirring method may be used. Examples of the mechanical stirring method include a method of circulating the washing liquid over the processing object, a method of passing the washing liquid over the processing object or spraying the washing liquid to the processing object, and a method of stirring the washing liquid using ultrasonic or megasonic waves.

### <Other Steps>

The method for producing a semiconductor device according to the present invention may include steps other than the above-described steps. Examples of the other steps include a pad cleaning step, a rinsing step, and a drying step.

### Pad Cleaning Step

The pad cleaning step is a step conducted between Step 1 and 2, in which residues present on the surface of the processing object are removed with the pad. Specifically, the surface of the processing object that has been subjected to CMP is brought into contact with the pad, and the processing object and the pad are slid relative to each other while a composition for pad cleaning is fed to the contact portion. As a result, the residues present on the surface of the processing object can be removed due to the frictional force produced by the pad and the chemical action produced by the composition for pad cleaning.

The pad is not limited and may be selected appropriately in accordance with the type of the processing object, the type of the residues that are to be removed, and the device used. The pad may be, for example, the polish pad used for CMP or a buffing pad, such as a polyurethane foam buffing pad, nonwoven fabric, suede buffing pad, or sponge. Note that the pad cleaning treatment using a pad includes a treatment referred to as buff cleaning or buff polishing.

The composition for pad cleaning may be selected from publicly known cleaning compositions appropriately in accordance with the type of the processing object and the type and amount of the residues that are to be removed. Examples of the constituents of the composition for pad cleaning include a water-soluble polymer, such as polyvinyl alcohol, a disperse medium, such as water, and an acid, such as nitric acid. The washing liquid included in the kit can be used as the composition for pad washing. Note that the composition for pad cleaning does not include abrasive grains.

The device used in the pad cleaning treatment and the conditions of the pad cleaning treatment may be selected from publicly known device and conditions appropriately in accordance with the type of the processing object and the type and amount of the residues that are to be removed. For example, the treatment method described in Paragraphs [0085] to [0088] of WO2017/169539A may be used. The contents of the above patent document are incorporated herein.

It is also preferable to perform the pad cleaning treatment using, as a composition for pad cleaning, a liquid prepared by removing the abrasive grains from the polishing fluid of the kit or the washing liquid of the kit. The washing liquid used in the pad cleaning treatment may be the diluted washing liquid.

### Rinsing Step

The rinsing step is a step of bringing the processing object into contact with a rinsing liquid. When the rinsing step is conducted, the processing object can be cleaned with the rinsing liquid and the defects present on the surface of the processing object can be removed with efficiency. The rinsing step is preferably conducted immediately subsequent to Step 2.

The rinsing step is preferably a step of rinsing the processing object with a rinsing liquid. The rinsing step may be conducted using the mechanical stirring method.

Examples of the rinsing liquid include water (preferably, DI water), methanol, ethanol, isopropyl alcohol (IPA), N-methylpyrrolidinone, γ-butyrolactone, dimethyl sulfoxide, ethyl lactate, and propylene glycol monomethyl ether acetate. An aqueous rinsing liquid having a pH of more than 8.0 (e.g., dilute aqueous ammonium hydroxide) may also be used.

For bringing the rinsing liquid into contact with the processing object, the above-described washing liquid may be brought into contact with the processing object.

The amount of time during which the processing object is brought into contact with the rinsing liquid may be changed appropriately in accordance with the types and contents of the constituents of the washing liquid, the target to which the washing liquid is used, and the purpose for which the washing liquid is used. Practically, the above time is preferably 10 to 120 seconds, is more preferably 20 to 90 seconds, and is further preferably 30 to 60 seconds.

### Drying Step

The drying step is a step of drying the processing object. When the drying step is conducted, the liquid constituents present on the surface of the processing object can be removed and the occurrence of defects in the subsequent steps can be reduced consequently.

The drying step is preferably conducted subsequent to Step 2 or the rinsing step. In the case where the production step includes the rinsing step, the drying step is more preferably conducted subsequent to the rinsing step.

Examples of the drying method include spin drying, a method of passing a dry gas over the processing object, a method of heating the substrate by heating means, such as a hot plate or an infrared lamp, Marangoni drying, Rotagoni drying, isopropyl alcohol (IPA) drying, and a combination of any of the above methods.

### Other Production Steps

The above-described production method may be performed before or after another step for substrate which is conducted in the production of an electronic device.

Examples of the other production step include steps of forming structures, such as a metal wire, a gate structure, a source structure, a drain structure, an insulation film, a ferromagnetic layer, and a non-magnetic layer (e.g., layer formation, etching, chemical mechanical polishing, and modification), a step of forming a resist, an exposure step, a removal step, a heat treatment step, a cleaning step, and an inspection step.

The production method may be performed in any of the following stages: back end of the line (BEOL), middle of the line (MOL), and front end of the line (FEOL). It is preferable to perform the production method in the front end of the line or the middle of the line.

### EXAMPLES

Further details of the present invention are described with reference to Examples below.

The materials described in Examples below, the amounts of the materials used in Examples, the proportions of the materials, details of the process performed in Examples, the steps for the process, and the like may be changed as needed without departing from the gist of the present invention. Therefore, Examples below should not be interpreted as restrictive of the scope of the present invention.

In Examples below, the pH values of polishing fluids and washing liquids were measured at 25 °C with a pH meter (produced by HORIBA, Ltd., model: “F-74”) in conformity with JIS Z 8802-1984.

In the production of washing liquids in Examples and Comparative Examples, the handling of containers, the preparation, charging, and storage of the washing liquids, and analysis and measurement were all conducted at 23 °C in a cleanroom of ISO class 2 or lower.

### <<Preparation of Members>>

### <Preparation of Polishing Fluids>

In each of Examples and Comparative Examples, a polishing fluid was prepared by mixing the raw materials described below (abrasive grains, a nonionic surfactant, an organic acid, an alcohol, an oxidizing agent, and other constituents) and water at the proportions described in Tables below. The pH values listed in Tables were adjusted by the addition of nitric acid and/or potassium hydroxide, which was used as a pH-controlling agent as needed. Note that the constituent of each of the polishing fluids which is other than the constituents listed in Tables, that is, the balance, includes water and a pH-controlling agent. The content of the pH-controlling agent was less than 1% by mass in any of Examples and Comparative Examples.

### (Abrasive Grains)

BS-1 (colloidal silica, produced by Fuso Chemical Co., Ltd.)

### (Nonionic Surfactant)

S-1 (EMULGEN 106, produced by Kao Corporation)
S-2 (EMULGEN 404, produced by Kao Corporation)
S-3 (RHEODOL TW-S320V, produced by Kao Corporation)
S-4 (RHEODOL 430V, produced by Kao Corporation)
S-5 (LF-EP-61, produced by Verdant Specialty Solutions)
S-6 (LF-EP-40, produced by Verdant Specialty Solutions)
S-7 (SURFYNOL 440, produced by Evonik Industries AG)
S-8 (SURFYNOL MD20, produced by Evonik Industries AG)

### (Organic Acid)

Citric acid
Malonic acid

### (Alcohol)

Methanol
Ethanol
Isopropanol
1-Propanol
   (Oxidizing agent)
Hydrogen peroxide

### (Other Constituent)

Benzotriazole (BTA)

### <Preparation of Washing Liquids>

Concentrates were prepared by mixing the raw materials described below (a first compound, a second compound, and other constituents) and water at the proportions described in Tables below. Note that the constituent of each of the concentrates of the washing liquids which is other than the constituents listed in Tables, that is, the balance, is water.

Subsequently, the concentrates were diluted with ultrapure water, which served as a diluent, at the respective dilution factors (volume basis) described in Tables to prepare washing liquids of Examples and Comparative Examples. The pH values of the washing liquids which are listed in Tables were adjusted by the addition of nitric acid and/or potassium hydroxide, which was used as a pH-controlling agent as needed. The content of the pH-controlling agent was less than 1% by mass in any of Examples and Comparative Examples.

### (First Compound)

Xanthine
Adenine

### (Second Compound)

2-(Dimethylamino)-2-methyl-1-propanol (DMAMP, compound represented by Formula (A1))
Ethyltrimethylammonium hydroxide (ETMAH)
Tris(2-hydroxyethyl)methylammonium hydroxide (THEMAH)
N,N,N′,N″,N″-pentamethyldiethylenetriamine (PMDTA, compound represented by Formula (A2))
N-methyldiethanolamine (MDEA, compound represented by Formula (A1))
2-Amino-2-methyl-1-propanol (AMP, compound represented by Formula (A1))
Triethylamine (TEA, compound represented by Formula (A3))
Trimethylamine (TMA, compound represented by Formula (A3))

### (Other Constituent)

Succinic acid (organic acid)

### <<Evaluations>>

The following evaluations were made using the polishing fluids and the washing liquids prepared in Examples and Comparative Examples.

### <Preparation of Processing Objects>

The processing objects used in the evaluations were prepared by performing bulk polishing of 12-inch wafers having a copper (Cu) wiring pattern (MIT754 (Cu/Ta/TaN/SiOC (corresponding to BDII) structure)) using the following procedure.

The conditions for bulk polishing are described below.

The above wafers were polished with a polishing device “FREX-300X” produced by Ebara Corporation under the following conditions while a slurry (CSL9044C produced by FUJIFILM Corporation) was fed.

### (Polishing Conditions)

Table rotation speed: 80 rpm
Head rotation speed: 78 rpm
Polishing pressure: 140 hPa
Polishing pad: VP6000 produced by Rodel Nitta Company
Polishing fluid feeding speed: 250 ml/L
Polishing time: In addition to the amount of time required to reach the endpoint of polishing, at which the signal generated when the barrier surface is exposed reaches a predetermined value or less, over polishing was performed for another five seconds.

### <Evaluation of Flatness>

The processing objects prepared in Preparation of Processing Objects were polished using the polishing fluids of Examples and Comparative Examples which were prepared by the above-described steps. The following polishing conditions were employed.
Table rotation speed: 80 rpm
Head rotation speed: 78 rpm
Polishing pressure: 105 hPa
Polishing pad: H800 produced by Fujibo Holdings Inc.
Polishing fluid feeding speed: 200 ml/L
Polishing time: 30 seconds

After polishing had been finished, using the corresponding one of the washing liquids of Examples and Comparative Examples which were prepared by the above-described steps, the polished surface of each of the polished processing objects was subjected to single wafer cleaning for 30 seconds by brush scrubbing in a cleaning unit 1 of the polishing device and subsequently subjected to further single wafer cleaning for 30 seconds in a cleaning unit 2. After rinsing had been performed for 60 seconds using pure water, in a drying unit, spin drying was performed at a rotation speed of 1000 rpm while a nitrogen gas was blown onto the wafer surface. Hereby, evaluation processing objects were prepared.

Subsequently, the flatness of each of the evaluation processing objects which was determined with a profilometer (Dektak XTL, produced by Bruker Corporation) was evaluated.

Using chips taken from the three positions of each of the processing objects, that is, the center of the processing object, the edge of the processing object, and the midpoint between the center and the edge, the erosion of the wire with L/S (line and space)=9/1 was measured with the profilometer. Flatness was evaluated by applying the following evaluation standard to the average of the values measured at the above three positions.

### Evaluation Standard

A: Erosion was less than 30 angstrom.
B: Erosion was 30 angstrom or more and less than 50 angstrom.
C: Erosion was 50 angstrom or more and less than 75 angstrom.
D: Erosion was 75 angstrom or more and less than 100 angstrom.
E: Erosion was 100 angstrom or more.

### <Evaluation of Removal of Organic Residue>

The polished surface of each of the evaluation processing objects prepared in Evaluation of Flatness was inspected for the number of organic residues using a defect inspection device (ComPlus II, produced by AMAT). Furthermore, organic residues (residues including an organic substance as a principal constituent) having a defect size of 60 nm or more were identified with Review SEM/EDX. An evaluation of removal of organic residues was made in accordance with the following evaluation standard. Note that the unit “counts/Wf” means the number of defects per wafer.

### Evaluation Standard

A: Total number of organic residues present on the substrate was less than 50 counts/Wf.
B: Total number of organic residues present on the substrate was 50 counts/Wf or more and less than 100 counts/Wf.
C: Total number of organic residues present on the substrate was 100 counts/Wf or more and less than 150 counts/Wf.
D: Total number of organic residues present on the substrate was 150 counts/Wf or more and less than 200 counts/Wf.
E: Total number of organic residues present on the substrate was 200 counts/Wf or more.

### <Evaluation of Roughness of Copper Surface>

Using the chips taken from the three positions on each of the evaluation processing objects obtained in Evaluation of Flatness above, that is, the center of the processing object, the edge of the processing object, and the midpoint between the center and the edge, surface roughness of a Cu wire with L/S=10/10 was measured over 5 μm with AFM (AFM550M, produced by Hitachi High-Tech Corporation). Roughness of copper surface was evaluated by applying the following evaluation standard to the average of the values measured at the above three positions.

### Evaluation Standard

A: Surface roughness was 3 angstrom or less.
B: Surface roughness was more than 3 angstrom and 5 angstrom or less.
C: Surface roughness was more than 5 angstrom and 10 angstrom or less.
D: Surface roughness was more than 10 angstrom and 20 angstrom or less.
E: Surface roughness was more than 20 angstrom.

### Results

Tables list the composition of the each of the polishing fluids prepared in Examples and Comparative Examples, the composition of the concentrate of each of the washing liquids prepared in Examples and Comparative Examples, the dilution factor of the washing liquid, and evaluation results.

In Tables, the columns “Content” each refer to the content (unit: % by mass) of the constituent relative to the total mass of the polishing fluid or the content (unit: % by mass) of the constituent relative to the total mass of the concentrate of the washing liquid. Note that the values in the column “Content” of “f) Alcohol” are in units of ppm by mass.

In Tables, the columns “Content (relative to solid content)” each refer to the content (unit: % by mass) of the constituent relative to the total solid content of the washing liquid. Note that the column “d) Content (relative to solid content)” refers to the mass ratio of the total content of all the second compounds in the washing liquid to the total solid content in the washing liquid.

In Tables, the columns “C log P” refer to the C log P value of the second compound which was calculated by drawing a structure using ChemDraw Professional (version 20.1.1.125) produced by PerkinElmer and performing computations using the software.

In Tables, the columns “pH” and “pH after dilution” refer to the pH of the polishing fluid, the concentrate of the washing liquid, or the washing liquid prepared in Examples and Comparative Examples which was measured with the pH meter at 25 °C.

In Tables, the column “(d)/(c)” refers to the mass ratio of the content of the second compound to the content of the first compound.

In Tables, the column “(b)/(d)” refers to the ratio of the content of the nonionic surfactant relative to the total mass of the polishing fluid to the content of the second compound relative to the total mass of the washing liquid.

In Tables, the column “Dilution factor (times)” refers to the dilution factor (volume ratio) used when the concentrate of the washing liquid having the composition described in Tables was used for the test. For example, in the case where the value in the column “Dilution factor (times)” is 200, a washing liquid prepared by diluting the concentrate having the composition described in Tables 200 times by volume with pure water used as a diluent was used for the above evaluations.

Tables 2, 4, and 6 are continuations of Tables 1, 3, and 5, respectively.

TABLE 1

| | Polishing fluid composition | | | | | | | | | | | | |
|---|---|---|---|---|---|---|---|---|---|---|---|---|---|
| | | | | | | | f) Alcohol | | | | | | |
| | a) Abrasive | | b) Nonionic | | | | | Content | | | | | |
| | grains | | surfactant | | e) Organic acid | | | (mass | Others | | | Oxilizing agent | |
| Table | Type | Content | Type | Content | Type | Content | Type | ppm) | Type | Content | pH | Type | Content |
| Example | BS-1 | 2 | S-1 | 0.05 | Citric | 0.2 | — | — | — | — | 7.5 | Hydrogen | 2 |
| 1 | | | | | acid | | | | | | | peroxide | |
| Example | BS-1 | 2 | S-1 | 0.05 | Citric | 0.2 | — | — | — | — | 10 | Hydrogen | 2 |
| 2 | | | | | acid | | | | | | | peroxide | |
| Example | BS-1 | 2 | S-1 | 0.05 | Citric | 0.2 | — | — | — | — | 10 | Hydrogen | 2 |
| 3 | | | | | acid | | | | | | | peroxide | |
| Example | BS-1 | 2 | S-1 | 0.05 | Citric | 0.2 | — | — | — | — | 10 | Hydrogen | 2 |
| 4 | | | | | acid | | | | | | | peroxide | |
| Example | BS-1 | 2 | S-1 | 0.05 | Citric | 0.2 | — | — | — | — | 10 | Hydrogen | 2 |
| 5 | | | | | acid | | | | | | | peroxide | |
| Example | BS-1 | 2 | S-1 | 0.05 | Citric | 0.2 | — | — | — | — | 10 | Hydrogen | 2 |
| 6 | | | | | acid | | | | | | | peroxide | |
| Example | BS-1 | 2 | S-1 | 0.05 | Citric | 0.2 | — | — | — | — | 10 | Hydrogen | 2 |
| 7 | | | | | acid | | | | | | | peroxide | |
| Example | BS-1 | 2 | S-1 | 0.05 | Citric | 0.2 | — | — | — | — | 10 | Hydrogen | 2 |
| 8 | | | | | acid | | | | | | | peroxide | |
| Example | BS-1 | 2 | S-1 | 0.05 | Citric | 0.2 | — | — | — | — | 10 | Hydrogen | 2 |
| 9 | | | | | acid | | | | | | | peroxide | |
| Example | BS-1 | 2 | S-1 | 0.05 | Citric | 0.2 | — | — | — | — | 10 | Hydrogen | 2 |
| 10 | | | | | acid | | | | | | | peroxide | |
| Example | BS-1 | 2 | S-1 | 0.05 | Citric | 0.2 | — | — | — | — | 10 | Hydrogen | 2 |
| 11 | | | | | acid | | | | | | | peroxide | |
| Example | BS-1 | 2 | S-1 | 0.05 | Citric | 0.2 | — | — | — | — | 10 | Hydrogen | 2 |
| 12 | | | | | acid | | | | | | | peroxide | |
| Example | BS-1 | 2 | S-1 | 0.05 | Citric | 0.2 | — | — | — | — | 10 | Hydrogen | 2 |
| 13 | | | | | acid | | | | | | | peroxide | |
| Example | BS-1 | 2 | S-1 | 0.05 | Citric | 0.2 | — | — | — | — | 10 | Hydrogen | 2 |
| 14 | | | | | acid | | | | | | | peroxide | |
| Example | BS-1 | 2 | S-1 | 0.05 | Citric | 0.2 | — | — | — | — | 10 | Hydrogen | 2 |
| 15 | | | | | acid | | | | | | | peroxide | |
| Example | BS-1 | 2 | S-1 | 0.05 | Citric | 0.2 | — | — | — | — | 10 | Hydrogen | 2 |
| 16 | | | | | acid | | | | | | | peroxide | |
| Example | BS-1 | 2 | S-1 | 0.05 | Citric | 0.2 | — | — | — | — | 10 | Hydrogen | 2 |
| 17 | | | | | acid | | | | | | | peroxide | |
| Example | BS-1 | 2 | S-1 | 0.05 | Citric | 0.2 | — | — | — | — | 10 | Hydrogen | 2 |
| 18 | | | | | acid | | | | | | | peroxide | |
| Example | BS-1 | 2 | S-1 | 0.05 | Citric | 0.2 | — | — | — | — | 10 | Hydrogen | 2 |
| 19 | | | | | acid | | | | | | | peroxide | |
| Example | BS-1 | 2 | S-1 | 0.05 | Citric | 0.2 | — | — | — | — | 10 | Hydrogen | 2 |
| 20 | | | | | acid | | | | | | | peroxide | |
| Example | BS-1 | 2 | S-1 | 0.05 | Citric | 0.2 | — | — | — | — | 10 | Hydrogen | 2 |
| 21 | | | | | acid | | | | | | | peroxide | |
| Example | BS-1 | 2 | S-1 | 0.05 | Citric | 0.2 | — | — | — | — | 10 | Hydrogen | 2 |
| 22 | | | | | acid | | | | | | | peroxide | |

TABLE 2

| | Washing liquid composition | | | | | | | | | | | | | | | | | | | |
|---|---|---|---|---|---|---|---|---|---|---|---|---|---|---|---|---|---|---|---|---|
| | c) First compound | | | | | | | | | d) | | | | | | | | | | |
| | | | Content | | | | | | | Content | | | | | | | | | Removal | |
| | | | (relative | | | | d2) or d3) Second | | | (relative | | | | | Dilution | pH | | | of | Roughness |
| | | | to solid | d1) Second compound | | | compound | | | to solid | Others | | | | factor | after | | | organic | of copper |
| | Type | Conte | content) | Type | Content | ClogP | Type | Content | ClogP | content) | Type | Content | (d)/(c) | pH | (times) | dilation | (b)/(d) | Flatness | residue | surface |
| Example 1 | Xanthine | 0.2 | 3.51 | ETMAH | 4 | — | MDEA | 1.5 | −1.33 | 96.49 | — | — | 27.50 | 14 | 30 | 10.8 | 0.2727 | C | B | B |
| Example 2 | Xanthine | 0.2 | 3.51 | ETMAH | 4 | — | MDEA | 1.5 | −1.31 | 96.49 | — | — | 27.50 | 14 | 30 | 10.8 | 0.2727 | B | B | B |
| Example 3 | Xanthine | 0.2 | 11.76 | PMDTA | 1.5 | 0.54 | — | — | — | 88.24 | — | — | 7.50 | 8 | 30 | 7.5 | 1.0000 | B | C | B |
| Example 4 | Xanthine | 0.2 | 3.51 | ETMAH | 4 | — | MDEA | 1.5 | −1.31 | 96.49 | — | — | 27.50 | 14 | 30 | 11 | 0.2727 | B | B | B |
| Example 5 | Xanthine | 0.2 | 3.51 | ETMAH | 4 | — | MDEA | 1.5 | −1.31 | 96.49 | — | — | 27.50 | 14 | 30 | 11.2 | 0.2727 | B | B | B |
| Example 6 | Xanthine | 0.2 | 4.76 | ETMAH | 4 | — | — | — | — | 95.24 | — | — | 20.00 | 14 | 30 | 10.8 | 0.3750 | B | C | B |
| Example 7 | Xanthine | 0.2 | 3.85 | ETMAH | 3.5 | — | MDEA | 1.5 | −1.31 | 96.15 | — | — | 25.00 | 14 | 30 | 11.2 | 0.3000 | B | B | B |
| Example 8 | Adenine | 0.2 | 3.85 | ETMAH | 3.5 | — | PMDTA | 1.5 | 0.54 | 96.15 | — | — | 25.00 | 14 | 30 | 10.8 | 0.3000 | B | B | B |
| Example 9 | Adenine | 0.05 | 0.90 | ETMAH | 4 | — | PMDTA | 1.5 | 0.54 | 99.10 | — | — | 110.00 | 14 | 30 | 10.8 | 0.2727 | B | B | B |
| Example 10 | Adenine | 0.2 | 9.09 | ETMAH | 1.5 | — | PMDTA | 0.5 | 0.54 | 90.91 | — | — | 10.00 | 14 | 30 | 10.8 | 0.7500 | B | B | B |
| Example 11 | Adenine | 0.2 | 11.11 | ETMAH | 1.5 | — | PMDTA | 0.1 | 0.54 | 88.89 | — | — | 8.00 | 14 | 30 | 10.8 | 0.9375 | B | B | C |
| Example 12 | Adenine | 0.2 | 25.00 | ETMAH | 0.5 | — | PMDTA | 0.1 | 0.54 | 75.00 | — | — | 3.00 | 13 | 30 | 10.8 | 2.5000 | B | C | B |
| Example 13 | Adenine | 0.2 | 3.51 | ETMAH | 5 | — | PMDTA | 0.5 | 0.54 | 96.49 | — | — | 27.50 | 14 | 30 | 10.8 | 0.2727 | B | B | B |
| Example 14 | Adenine | 0.2 | 3.23 | ETMAH | 5 | — | PMDTA | 1 | 0.54 | 96.77 | — | — | 30.00 | 14 | 30 | 10.8 | 0.2500 | B | B | B |
| Example 15 | Adenine | 0.2 | 1.96 | ETMAH | 5 | — | PMDTA | 5 | 0.54 | 98.04 | — | — | 50.00 | 14 | 30 | 10.8 | 0.1500 | B | B | B |
| Example 16 | Adenine | 0.2 | 1.32 | ETMAH | 5 | — | PMDTA | 10 | 0.54 | 98.68 | — | — | 75.00 | 14 | 30 | 10.8 | 0.1000 | B | B | B |
| Example 17 | Adenine | 0.5 | 8.33 | ETMAH | 4 | — | PMDTA | 1.5 | 0.54 | 91.67 | — | — | 11.00 | 14 | 30 | 10.8 | 0.2727 | B | B | B |
| Example 18 | Adenine | 0.2 | 3.45 | DMAMP | 4 | — | PMDTA | 1.5 | 0.54 | 96.55 | — | — | 28.00 | 11 | 30 | 10.8 | 0.2679 | B | A | B |
| | | | | | | | AMP | 0.1 | 0.61 | | | | | | | | | | | |
| Example 19 | Adenine | 0.2 | 3.51 | DMAMP | 4 | 0.37 | PMDTA | 1.5 | 0.54 | 96.49 | — | — | 27.50 | 11 | 30 | 10.8 | 0.2727 | B | B | B |
| Example 20 | Adenine | 0.2 | 3.70 | DMAMP | 4 | 0.37 | AMP | 1.2 | 0.61 | 96.30 | — | — | 26.00 | 11 | 30 | 10.8 | 0.2885 | B | B | B |
| Example 21 | Adenine | 0.2 | 3.64 | DMAMP | 4 | 0.37 | MDEA | 1.2 | −0.72 | 96.36 | — | — | 26.50 | 11 | 30 | 10.8 | 0.2830 | B | A | B |
| | | | | | | | AMP | 0.1 | 0.61 | | | | | | | | | | | |
| Example 22 | Adenine | 0.2 | 3.38 | DMAMP | 4 | 0.37 | PMDTA | 1.5 | 0.54 | 94.59 | Succinic | 0.12 | 28.00 | 11 | 30 | 10.9 | 0.2679 | B | A | A |
| | | | | | | | AMP | 0.1 | 0.61 | | acid | | | | | | | | | |

TABLE 3

| | Polishing fluid composition | | | | | | | | | | | | |
|---|---|---|---|---|---|---|---|---|---|---|---|---|---|
| | | | | | | | f) Alcohol | | | | | | |
| | a) Abrasive | | b) Nonionic | | | | | Content | | | | | |
| | grains | | surfactant | | e) Organic acid | | | (mass | Others | | | Oxidizing agent | |
| | Type | Content | Type | Content | Type | Content | Type | ppm) | Type | Content | pH | Type | Content |
| Example | BS-1 | 2 | S-1 | 0.05 | Malonic | 0.2 | — | — | — | — | 10 | Hydrogen | 2 |
| 23 | | | | | acid | | | | | | | peroxide | |
| Example | BS-1 | 2 | S-1 | 0.05 | Malonic | 0.2 | — | — | — | — | 10 | Hydrogen | 2 |
| 24 | | | | | acid | | | | | | | peroxide | |
| | | | | | Citric | 0.05 | | | | | | | |
| | | | | | acid | | | | | | | | |
| Example | BS-1 | 2 | S-1 | 0.05 | Citric | 0.2 | Methanol | 0.1 | — | — | 10 | Hydrogen | 2 |
| 25 | | | | | acid | | | | | | | peroxide | |
| Example | BS-1 | 2 | S-1 | 0.05 | Citric | 0.2 | Methanol | 1 | — | — | 10 | Hydrogen | 2 |
| 26 | | | | | acid | | | | | | | peroxide | |
| Example | BS-1 | 2 | S-1 | 0.05 | Citric | 0.2 | Methanol | 1 | — | — | 10 | Hydrogen | 2 |
| 27 | | | | | acid | | | | | | | peroxide | |
| Example | BS-1 | 2 | S-1 | 0.05 | Citric | 0.2 | Methanol | 1 | — | — | 10 | Hydrogen | 2 |
| 28 | | | | | acid | | | | | | | peroxide | |
| Example | BS-1 | 2 | S-1 | 0.05 | Citric | 0.2 | Methanol | 10 | — | — | 10 | Hydrogen | 2 |
| 29 | | | | | acid | | | | | | | peroxide | |
| Example | BS-1 | 2 | S-1 | 0.05 | Citric | 0.2 | Methanol | 80 | — | — | 10 | Hydrogen | 2 |
| 30 | | | | | acid | | | | | | | peroxide | |
| Example | BS-1 | 2 | S-1 | 0.05 | Citric | 0.2 | Methanol | 1000 | — | — | 10 | Hydrogen | 2 |
| 31 | | | | | acid | | | | | | | peroxide | |
| Example | BS-1 | 2 | S-1 | 0.05 | Citric | 0.2 | Methanol | 2500 | — | — | 10 | Hydrogen | 2 |
| 32 | | | | | acid | | | | | | | peroxide | |
| Example | BS-1 | 2 | S-1 | 0.05 | Citric | 0.2 | Ethanol | 80 | — | — | 10 | Hydrogen | 2 |
| 33 | | | | | acid | | | | | | | peroxide | |
| Example | BS-1 | 2 | S-1 | 0.05 | Citric | 0.2 | Isopropanol | 80 | — | — | 10 | Hydrogen | 2 |
| 34 | | | | | acid | | | | | | | peroxide | |
| Example | BS-1 | 2 | S-1 | 0.05 | Citric | 0.2 | 1-Propanol | 80 | — | — | 10 | Hydrogen | 2 |
| 35 | | | | | acid | | | | | | | peroxide | |
| Example | BS-1 | 2 | S-1 | 0.05 | Citric | 0.2 | Methanol | 80 | BTA | 0.004 | 10 | Hydrogen | 2 |
| 36 | | | | | acid | | | | | | | peroxide | |
| Example | BS-1 | 2 | S-2 | 0.05 | Citric | 0.2 | Methanol | 80 | BTA | 0.004 | 10 | Hydrogen | 2 |
| 37 | | | | | acid | | | | | | | peroxide | |
| Example | BS-1 | 2 | S-2 | 0.05 | Citric | 0.2 | Methanol | 80 | BTA | 0.004 | 10 | Hydrogen | 2 |
| 38 | | | | | acid | | | | | | | peroxide | |
| Example | BS-1 | 2 | S-3 | 0.05 | Citric | 0.2 | Methanol | 80 | BTA | 0.004 | 10 | Hydrogen | 2 |
| 39 | | | | | acid | | | | | | | peroxide | |
| Example | BS-1 | 2 | S-4 | 0.05 | Citric | 0.2 | Methanol | 80 | BTA | 0.004 | 10 | Hydrogen | 2 |
| 40 | | | | | acid | | | | | | | peroxide | |
| Example | BS-1 | 2 | S-5 | 0.05 | Citric | 0.2 | Methanol | 80 | BTA | 0.004 | 10 | Hydrogen | 2 |
| 41 | | | | | acid | | | | | | | peroxide | |
| Example | BS-1 | 2 | S-6 | 0.05 | Citric | 0.2 | Methanol | 80 | BTA | 0.004 | 10 | Hydrogen | 2 |
| 42 | | | | | acid | | | | | | | peroxide | |
| Example | BS-1 | 2 | S-7 | 0.05 | Citric | 0.2 | Methanol | 80 | BTA | 0.004 | 10 | Hydrogen | 2 |
| 43 | | | | | acid | | | | | | | peroxide | |
| Example | BS-1 | 2 | S-8 | 0.05 | Citric | 0.2 | Methanol | 80 | BTA | 0.004 | 10 | Hydrogen | 2 |
| 44 | | | | | acid | | | | | | | peroxide | |
| Example | BS-1 | 2 | S-6 | 1 | Citric | 0.2 | Methanol | 80 | BTA | 0.004 | 10 | Hydrogen | 2 |
| 45 | | | | | acid | | | | | | | peroxide | |

TABLE 4

| | Washing liquid composition | | | | | | | | | | | | | | | | | | | |
|---|---|---|---|---|---|---|---|---|---|---|---|---|---|---|---|---|---|---|---|---|
| | c) First compound | | | | | | | | | | | | | | | | | | | |
| | | | Content | | | | | | | d) Content | | | | | | | | | Removal | |
| | | | (relative | d1) Second | | | d2) or d3) Second | | | (relative to | | | | | Dilution | pH | | | of | Roughness |
| | | | to solid | compound | | | compound | | | solid | Others | | | | factor | after | | | organic | of copper |
| | Type | Content | content) | Type | Content | ClogP | Type | Content | ClogP | content) | Type | Content | (d)/(c) | pH | (times) | dilution | (b)/(d) | Flatness | residune | surface |
| Example 23 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | B | B |
| Example 24 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | B | B |
| Example 25 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 26 | Adenine | 0.2 | 3.70 | DMAMP | 4 | 0.37 | AMP | 1.2 | 0.61 | 96.30 | — | — | 26.00 | 11 | 30 | 10.9 | 0.2885 | B | A | B |
| Example 27 | Adenine | 0.2 | 3.45 | DMAMP | 4 | 0.37 | PMDTA | 1.5 | 0.54 | 96.55 | — | — | 28.00 | 11 | 30 | 10.9 | 0.2632 | B | A | B |
| | | | | | | | AMP | 0.1 | 0.61 | | | | | | | | | | | |
| Example 28 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 29 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 30 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 31 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 32 | Adenine | 0.2 | 3.51 | DMAMP | 4 | 0.37 | PMDTA | 1.5 | 0.54 | 96.49 | — | — | 27.50 | 11 | 30 | 10.9 | 0.2737 | B | A | B |
| Example 33 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | C |
| Example 34 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 35 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 36 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | A | A | B |
| Example 37 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | A | A | B |
| Example 38 | Adenine | 0.2 | 33.33 | DMAMP | 0.2 | 0.37 | PMDTA | 0.2 | 0.54 | 66.67 | — | — | 2.00 | 11 | 30 | 10.9 | 3.7500 | A | B | B |
| Example 39 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 40 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 41 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | A | A | B |
| Example 42 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | A | A | B |
| Example 43 | Admins | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 44 | Adenine | 0.2 | 3.51 | DMAMP | 4 | 0.37 | PMDTA | 1.5 | 0.54 | 96.49 | — | — | 27.50 | 11 | 30 | 10.9 | 0.2727 | B | A | B |
| Example 45 | Adenine | 0.2 | 3.45 | DMAMP | 4 | — | PMDTA | 1.5 | 0.54 | 96.55 | — | — | 28.00 | 11 | 30 | 11.2 | 5.3571 | A | B | A |
| | | | | | | | AMP | 0.1 | 0.61 | | | | | | | | | | | |

TABLE 5

| | Polishing fluid composition | | | | | | | | | | | | |
|---|---|---|---|---|---|---|---|---|---|---|---|---|---|
| | | | | | | | f) Alcohol | | | | | | |
| | a) Abrasive | | b) Nonionic | | | | | Content | | | | | |
| | grams | | surfactant | | e) Organic acid | | | (mass | Others | | | Oxidizing agent | |
| | Type | Content | Type | Content | Type | Content | Type | ppm) | Type | Content. | pH | Type | Content |
| Example 46 | BS-1 | 2 | S-6 | 1 | Citric | 0.2 | Methanol | 80 | BTA | 0.004 | 10 | Hydrogen | 2 |
| | | | | | acid | | | | | | | peroxide | |
| Example 47 | BS-1 | 2 | S-6 | 0.71 | Citric | 0.2 | Methanol | 80 | BTA | 0.004 | 10 | Hydrogen | 2 |
| | | | | | acid | | | | | | | peroxide | |
| Example 48 | BS-1 | 2 | S-6 | 0.1 | Citric | 0.2 | Methanol | 80 | BTA | 0.004 | 10 | Hydrogen | 2 |
| | | | | | acid | | | | | | | peroxide | |
| Example 49 | BS-1 | 2 | S-6 | 0.005 | Citric | 0.2 | Methanol | 80 | BTA | 0.004 | 10 | Hydrogen | 2 |
| | | | | | acid | | | | | | | peroxide | |
| Example 50 | BS-1 | 2 | S-6 | 0.002 | Citric | 0.2 | Methanol | 80 | BTA | 0.004 | 10 | Hydrogen | 2 |
| | | | | | acid | | | | | | | peroxide | |
| Example 51 | BS-1 | 2 | S-6 | 0.001 | Citric | 0.2 | Methanol | 80 | BTA | 0.004 | 10 | Hydrogen | 2 |
| | | | | | acid | | | | | | | peroxide | |
| Example 52 | BS-1 | 2 | S-6 | 0.001 | Citric | 0.2 | Methanol | 80 | BTA | 0.004 | 10 | Hydrogen | 2 |
| | | | | | acid | | | | | | | peroxide | |
| Example 53 | BS-1 | 2 | S-6 | 0.001 | Citric | 0.2 | Methanol | 80 | BTA | 0.004 | 10 | Hydrogen | 2 |
| | | | | | acid | | | | | | | peroxide | |
| Example 54 | BS-1 | 2 | S-6 | 0.001 | Citric | 0.2 | Methanol | 80 | BTA | 0.004 | 10 | Hydrogen | 2 |
| | | | | | acid | | | | | | | peroxide | |
| Example 55 | BS-1 | 2 | S-6 | 0.001 | Citric | 0.2 | Methanol | 80 | BTA | 0.004 | 10 | Hydrogen | 2 |
| | | | | | acid | | | | | | | peroxide | |
| Example 56 | BS-1 | 2 | S-6 | 0.001 | Citric | 0.2 | Methanol | 80 | BTA | 0.004 | 10 | Hydrogen | 2 |
| | | | | | acid | | | | | | | peroxide | |
| Comparative | BS-1 | 2 | — | — | Citric | 0.2 | — | — | BTA | 0.004 | 10 | Hydrogen | 2 |
| Example 1 | | | | | acid | | | | | | | peroxide | |
| Comparative | BS-1 | 2 | S-1 | 0.05 | Citric | 0.2 | Methanol | 0.1 | — | — | 10 | Hydrogen | 2 |
| Example 2 | | | | | acid | | | | | | | peroxide | |
| Comparative | BS-1 | 2 | — | — | Citric | 0.2 | — | — | BTA | 0.004 | 10 | Hydrogen | 2 |
| Example 3 | | | | | acid | | | | | | | peroxide | |

TABLE 6

| | Washing liquid composition | | | | | | | | | | | | | | | | | | | |
|---|---|---|---|---|---|---|---|---|---|---|---|---|---|---|---|---|---|---|---|---|
| | c) First compound | | | | | | | | | d) | | | | | | | | | | |
| | | | Content | | | | | | | Content | | | | | | | | | Removal | |
| | | | (relative | d1) Second | | | d2) or d3) Second | | | (relative | | | | | Dilution | | | | of | Roughness |
| | | | to solid | compound | | | compound | | | to solid | Others | | | | factor | pH after | | Flat- | organic | of copper |
| | Type | Content | content) | Type | Content | ClogP | Type | Content | ClogP | content) | Type | Content | (d)/(c) | pH | (times) | dilution | (b)/(d) | ness | residue | surface |
| Example 46 | Xanthine | 0.2 | 2.73 | THEMAH | 5.5 | — | MDEA | 1.5 | −1.31 | 95.63 | Succinic | 0.12 | 35.00 | 13 | 30 | 11.2 | 4.2857 | A | B | A |
| | | | | | | | | | | | acid | | | | | | | | | |
| Example 47 | Xanthine | 0.2 | 2.73 | THEMAH | 5.5 | — | MDEA | 1.5 | −1.31 | 95.63 | Succinic | 0.12 | 35.00 | 13 | 30 | 11.2 | 3.0429 | A | A | A |
| | | | | | | | | | | | acid | | | | | | | | | |
| Example 48 | Xanthine | 0.2 | 2.73 | THEMAH | 5.5 | — | MDEA | 1.5 | −1.31 | 95.63 | Succinic | 0.12 | 35.00 | 13 | 30 | 11.2 | 0.4286 | A | A | A |
| | | | | | | | | | | | acid | | | | | | | | | |
| Example 49 | Xanthine | 0.2 | 2.73 | THEMAH | 5.5 | — | MDEA | 1.5 | −1.31 | 95.63 | Succinic | 0.12 | 35.00 | 13 | 30 | 11.2 | 0.0214 | A | A | A |
| | | | | | | | | | | | acid | | | | | | | | | |
| Example 50 | Xanthine | 0.2 | 2.73 | THEMAH | 5.5 | — | MDEA | 1.5 | −1.31 | 95.63 | Succinic | 0.12 | 35.00 | 13 | 30 | 11.2 | 0.0086 | A | A | A |
| | | | | | | | | | | | acid | | | | | | | | | |
| Example 51 | Xanthine | 0.2 | 2.73 | THEMAH | 5.5 | — | MDEA | 1.5 | −1.31 | 95.63 | Succinic | 0.12 | 35.00 | 13 | 30 | 11.2 | 0.0043 | A | A | A |
| | | | | | | | | | | | acid | | | | | | | | | |
| Example 52 | Xanthine | 0.2 | 2.73 | THEMAH | 5.5 | — | MDEA | 1.5 | −1.31 | 95.63 | Succinic | 0.12 | 35.00 | 13 | 10 | 12.2 | 0.0014 | B | A | B |
| | | | | | | | | | | | acid | | | | | | | | | |
| Example 53 | Xanthine | 0.2 | 2.73 | THEMAH | 5.5 | — | MDEA | 1.5 | −1.31 | 95.63 | Succinic | 0.12 | 35.00 | 13 | 100 | 11 | 0.0143 | A | A | A |
| | | | | | | | | | | | acid | | | | | | | | | |
| Example 54 | Xanthine | 0.2 | 2.73 | THEMAH | 5.5 | — | MDEA | 1.5 | −1.31 | 95.63 | Succinic | 0.12 | 35.00 | 13 | 200 | 10.8 | 0.0286 | A | A | A |
| | | | | | | | | | | | acid | | | | | | | | | |
| Example 55 | Xanthine | 0.2 | 2.73 | THEMAH | 5.5 | — | MDEA | 1.5 | −1.31 | 95.63 | Succinic | 0.12 | 35.00 | 13 | 250 | 10.5 | 0.0357 | A | A | A |
| | | | | | | | | | | | acid | | | | | | | | | |
| Example 56 | Xanthine | 0.2 | 2.73 | THEMAH | 5.5 | — | MDEA | 1.5 | −1.31 | 95.63 | Succinic | 0.12 | 35.00 | 13 | 300 | 10.3 | 0.0429 | A | A | A |
| | | | | | | | | | | | acid | | | | | | | | | |
| Comparative | — | — | — | — | — | — | PMDTA | 1.5 | 0.54 | 100.00 | — | — | — | 9 | 30 | 8.5 | — | E | E | E |
| Example 1 | | | | | | | | | | | | | | | | | | | | |
| Comparative | — | — | — | — | — | — | PMDTA | 1.5 | 0.54 | 100.00 | — | — | — | 9 | 30 | 8.5 | 0.0011 | A | E | E |
| Example 2 | | | | | | | | | | | | | | | | | | | | |
| Comparative | Adenine | 0.2 | 1.83 | THEMAH | 5.5 | — | PMDTA | 5 | 0.54 | 97.07 | Succinic | 0.12 | 43.00 | 13 | 30 | 11.2 | — | E | A | D |
| Example 3 | | | | | | | TEA | 0.1 | | | acid | | | | | | | | | |

As described in Tables, it was confirmed that, when the kit according to the present invention is used for the process in which a processing object is subjected to chemical mechanical polishing and the processing object that has been subjected to chemical mechanical polishing is cleaned, the processing object has excellent flatness and organic residues are not likely to remain on the processing object.

A comparison between Examples 1 and 2 and the like confirmed that the advantageous effects of the present invention may be further enhanced when the pH of the polishing fluid is 8.5 to 11.0.

A comparison among Examples 2 to 5 and the like confirmed that the advantageous effects of the present invention may be further enhanced when the pH of the washing liquid is 10.0 to 14.0.

A comparison between Examples 6 and 7 and the like confirmed that the advantageous effects of the present invention may be further enhanced in the case where the washing liquid includes two or more second compounds.

A comparison among Examples 9 to 12 and the like confirmed that further excellent results may be obtained in terms of at least one of removal of organic residues or roughness of copper surface in the case where the mass ratio of the content of the second compound to the content of the first compound in the washing liquid is 10.00 to 1000.00.

A comparison between Examples 37 and 38 and the like confirmed that further excellent results may be obtained in terms of removal of organic residues in the case where the ratio of the content of the second compound in the washing liquid to the total solid content in the washing liquid is 75.0% by mass or more.

A comparison among Examples 11 to 17 and the like confirmed that further excellent results may be obtained in terms of at least one of removal of organic residues or roughness of copper surface in the case where the ratio of the content of the first compound in the washing liquid to the total solid content in the washing liquid is 0.10% to 10.0% by mass.

A comparison among Examples 18 to 21 and the like confirmed that further excellent results may be obtained in terms of removal of organic residues in the case where the washing liquid includes three or more second compounds.

A comparison between Examples 21 and 22 and the like confirmed that roughness of copper surface may be further reduced in the case where the washing liquid further includes an organic acid.

A comparison among Examples 23 to 31 and the like confirmed that further excellent results may be obtained in terms of removal of organic residues in the case where the polishing fluid further includes an alcohol.

A comparison among Examples 28 to 32 and the like confirmed that roughness of copper surface may be further reduced in the case where the ratio of the content of alcohol to the total mass of the polishing fluid is 0.1 to 1000 ppm by mass.

A comparison among Examples 36 to 44 and the like confirmed that the flatness of the processing object may be further enhanced in the case where the nonionic surfactant is an alcohol alkoxylate.

A comparison among Examples 46 to 56 and the like confirmed that further excellent results may be obtained in terms of at least one of flatness, removal of organic residues, or roughness of copper surface in the case where the ratio of the content of the nonionic surfactant relative to the total mass of the polishing fluid to the content of the second compound relative to the total mass of the washing liquid is 0.0035 to 3.5.

What is claimed is:

1. A kit used for chemical mechanical polishing of a processing object and cleaning of the processing object that has been subjected to the chemical mechanical polishing, the kit comprising:
a polishing fluid; and
a washing liquid,
the polishing fluid including abrasive grains and a nonionic surfactant, the polishing fluid having a pH of 7.0 or more,
the washing liquid including at least one first compound selected from the group consisting of xanthine, a xanthine derivative, adenine, and an adenine derivative and at least one second compound other than the first compound, the second compound being selected from the group consisting of a secondary amine compound, a tertiary amine compound, and a quaternary ammonium compound.

2. The kit according to claim 1,
wherein the washing liquid has a pH of 10.0 to 14.0.

3. The kit according to claim 1,
wherein the washing liquid includes two or more second compounds.

4. The kit according to claim 3,
wherein at least one of the two or more second compounds is a tertiary amine compound.

5. The kit according to claim 3,
wherein the washing liquid includes three or more second compounds.

6. The kit according to claim 5,
wherein at least one of the three or more second compounds is a tertiary amine.

7. The kit according to claim 1,
wherein at least one of the second compound is a compound selected from the group consisting of a compound represented by Formula (A1) and a compound represented by Formula (A2), 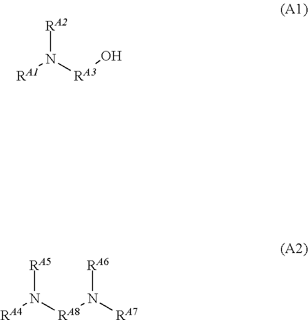
wherein, in Formula (A1),
R^{A1} and R^{A2} each independently represent a hydrogen atom or an unsubstituted or substituted alkyl group having 1 to 3 carbon atoms, where at least one of R^{A1} or R^{A2} represents an unsubstituted or substituted alkyl group having 1 to 3 carbon atoms,
R^{A3} represents an unsubstituted or substituted alkylene group having 1 to 4 carbon atoms, and
two of R^{A1} to R^{A3} may be bonded to each other with a single bond or a divalent linking group interposed therebetween to form a ring, and
wherein, in Formula (A2),
R^{A4} to R^{A7} each independently represent a hydrogen atom or a unsubstituted or substituted alkyl group having 1 to 3 carbon atoms, where at least one of R^{A4} to R^{A7} represents an unsubstituted or substituted alkyl group,
two of R^{A4} to R^{A7} may be bonded to each other with a single bond or a divalent linking group interposed therebetween to form a ring, and
R^{A8} represents an unsubstituted or substituted alkylene group having 1 to 6 carbon atoms which may have a linking group represented by —NR^{Ax}— or —O—, where R^{Ax} represents a hydrogen atom or an alkyl group having 1 to 3 carbon atoms.

8. The kit according to claim 7,
wherein the washing liquid includes two or more second compounds, and
at least two of the two or more second compounds are compounds selected from the group consisting of the compound represented by Formula (A1) and the compound represented by Formula (A2).

9. The kit according to claim 1,
wherein a content of the first compound is 0.10% to 10.0% by mass of a total solid content in the washing liquid.

10. The kit according to claim 1,
wherein a content of the second compound is 75.08 by mass or more of a total solid content in the washing liquid.

11. The kit according to claim 1,
wherein a mass ratio of a content of the second compound to a content of the first compound is 10.00 to 1000.00.

12. The kit according to claim 1,
wherein the pH of the polishing fluid is 8.5 to 11.0.

13. The kit according to claim 1,
wherein at least one of the polishing fluid or the washing liquid further includes an organic acid.

14. The kit according to claim 13,
wherein the organic acid includes at least one organic acid selected from the group consisting of a polyvalent carboxylic acid and a polyvalent phosphonic acid.

15. The kit according to claim 1,
wherein the polishing fluid further includes an alcohol.

16. The kit according to claim 15,
wherein a content of the alcohol is 0.1 to 1000 ppm by mass of a total mass of the polishing fluid.

17. The kit according to claim 15,
wherein the alcohol is an alcohol selected from the group consisting of methanol, ethanol, 1-propanol, and isopropanol.

18. The kit according to claim 1,
wherein the nonionic surfactant is an alcohol alkoxylate.

19. The kit according to claim 1,
wherein a ratio of a content of the nonionic surfactant relative to a total mass of the polishing fluid to a content of the second compound relative to a total mass of the washing liquid is 0.0035 to 3.5.

20. The kit according to claim 1,
wherein the processing object includes copper.

21. A method for producing a semiconductor device in which the kit according to claim 1 is used, the method comprising:
a step 1 of subjecting a processing object to chemical mechanical polishing using the polishing fluid, and
a step 2 of, subsequent to the step 1, cleaning the processing object that has been subjected to the chemical mechanical polishing using the washing liquid.

22. The method according to claim 21, further comprising:
a step 1a, after step 1 and prior to step 2, of pad washing the processing object subjected to chemical mechanical polishing using the washing liquid as a composition for pad washing.
